(19) United States
(12) Patent Application Publication
(10) Pub. No.: US 2024/0355853 A1
(43) Pub. Date: Oct. 24, 2024

(54) PHOTODETECTION DEVICE AND ELECTRONIC DEVICE

(71) Applicant: SONY SEMICONDUCTOR SOLUTIONS CORPORATION, KANAGAWA (JP)

(72) Inventor: KOHEI DOI, KANAGAWA (JP)

(21) Appl. No.: 18/294,686

(22) PCT Filed: Mar. 11, 2022
(86) PCT No.: PCT/JP2022/010753

§ 371 Date: Feb. 2, 2024

(30) Foreign Application Priority Data
Aug. 17, 2021 (JP) 2021-132695

(51) Int. Cl. H01L 27/146

(52) U.S. Cl. CPC H01L 27/14627; H01L 27/14607; H01L 27/14621; H01L 27/1463

(57) ABSTRACT

Provided is a photodetection device that is able to achieve both suppression of optical color mixing at normal pixels and an enhancement in the sensitivity ratio of phase difference pixels. The photodetection device includes individual-type microlenses each formed for a separate one of photoelectric conversion parts included in the normal pixels, and shared-type microlenses each formed for a separate one of photoelectric conversion part groups each including photoelectric conversion parts included in adjacent ones of the phase difference pixels. The photodetection device also includes first pixel separating portions arranged between at least some of the photoelectric conversion parts in each photoelectric conversion part group, and second pixel separating portions arranged between the photoelectric conversion parts where none of the first pixel separating portions is arranged. In addition, an end portion of each first pixel separating portion on a side closer to a light receiving surface is positioned on the side of the light receiving surface closer to a surface of a substrate opposite to the light receiving surface, while an end portion of each second pixel separating portion on the side closer to the light receiving surface is positioned closer to the light receiving surface than is the end portion of the first pixel separating portion on the side closer to the light receiving surface.

### TECHNICAL FIELD

The present disclosure relates to a photodetection device and an electronic device.

### BACKGROUND ART

A photodetection device including normal pixels and phase difference pixels in which, with respect to the phase difference pixels, one shared microlens is formed for multiple phase difference pixels, has previously been proposed (see, for example, PTL 1). In the photodetection device described in PTL 1, phase difference information is computed on the basis of pixel signals outputted from photoelectric conversion parts of the phase difference pixels to perform focus control.

In addition, the photodetection device described in PTL 1 includes pixel separating portions having trench portions and arranged between photoelectric conversion parts in a substrate to suppress optical color mixing at the normal pixels.

### CITATION LIST

### Patent Literature

[PTL 1]
PCT Patent Publication No. WO2016/098640

### SUMMARY

### Technical Problem

However, in the photodetection device described in PTL 1, at the phase difference pixels, the pixel separating portion lies in the vicinity of a point onto which the microlens concentrates light, and therefore, if incident light impinges on a surface of the pixel separating portion on a side closer to the microlens, for example, the incident light may be scattered at the pixel separating portion, resulting in a reduction in a sensitivity ratio (i.e., information about a difference in sensitivity between left and right pixels) of the phase difference pixels. In addition, if incident light traveling obliquely impinges on a side surface of the pixel separating portion, for example, the incident light may be reflected by the pixel separating portion to be guided toward a photoelectric conversion part different from the photoelectric conversion part toward which the incident light had been traveling, resulting in a reduction in the sensitivity ratio of the phase difference pixels.

An object of the present disclosure is to provide a photodetection device and an electronic device which are able to achieve both suppression of optical color mixing at normal pixels and an enhancement in the sensitivity ratio of phase difference pixels.

### Solution to Problem

A photodetection device according to the present disclosure includes (a) a substrate, (b) multiple pixels arranged two-dimensionally in the substrate, and including photoelectric conversion parts, (c) a microlens layer arranged on a side of the substrate on which a light receiving surface of the substrate lies, and including multiple microlenses for concentrating incident light onto the photoelectric conversion parts, and (d) pixel separating portions arranged between the photoelectric conversion parts in the substrate, and having trench portions, in which (e) the multiple pixels include normal pixels and phase difference pixels, (f) the multiple microlenses include individual-type microlenses each formed for a separate one of the photoelectric conversion parts included in the normal pixels, and shared-type microlenses each formed for a separate one of photoelectric conversion part groups each including the photoelectric conversion parts included in adjacent ones of the phase difference pixels, and (f) the pixel separating portions include first pixel separating portions arranged between at least some of the photoelectric conversion parts in each photoelectric conversion part group, and second pixel separating portions arranged between the photoelectric conversion parts where none of the first pixel separating portions is arranged, and an end portion of each first pixel separating portion on a side closer to the light receiving surface is positioned on a side of the light receiving surface of the substrate closer to a surface of the substrate opposite to the light receiving surface, while an end portion of each second pixel separating portion on the side closer to the light receiving surface is positioned closer to the light receiving surface than is the end portion of the first pixel separating portion on the side closer to the light receiving surface.

An electronic device according to the present disclosure includes a photodetection device including (a) a substrate, (b) multiple pixels arranged two-dimensionally in the substrate, and including photoelectric conversion parts, (c) a microlens layer arranged on a side of the substrate on which a light receiving surface of the substrate lies, and including multiple microlenses for concentrating incident light onto the photoelectric conversion parts, and (d) pixel separating portions arranged between the photoelectric conversion parts in the substrate, and having trench portions, in which (e) the multiple pixels include normal pixels each having an individual microlens formed for the photoelectric conversion part thereof, and phase difference pixels having shared-type microlenses formed for the photoelectric conversion parts thereof, each shared-type microlens being shared by a photoelectric conversion part group including adjacent ones of the photoelectric conversion parts, and (f) the pixel separating portions include first pixel separating portions arranged between at least some of the photoelectric conversion parts in each photoelectric conversion part group, and second pixel separating portions arranged between the photoelectric conversion parts where none of the first pixel separating portions is arranged, and an end portion of each first pixel separating portion on a side closer to the light receiving surface is positioned on a side of the light receiving surface of the substrate closer to a surface of the substrate opposite to the light receiving surface, while an end portion of each second pixel separating portion on the side closer to the light receiving surface is positioned closer to the light receiving surface than is the end portion of the first pixel separating portion on the side closer to the light receiving surface.

### BRIEF DESCRIPTION OF DRAWINGS

FIG. 1 is a diagram illustrating the overall structure of a solid-state imaging device according to a first embodiment.

FIG. 2 is a diagram illustrating the circuit configuration of pixels of the solid-state imaging device.

FIG. 3A is a diagram illustrating the structure of a section of the solid-state imaging device taken along line A-A in FIG. 1.

FIG. 3B is a diagram illustrating the planar structure of the solid-state imaging device in the case where FIG. 3A is viewed from a side on which a microlens layer lies.

FIG. 3C is a diagram illustrating the structure of a section of the solid-state imaging device taken along line B-B in FIG. 3A.

FIG. 3D is a diagram illustrating the structure of a section of the solid-state imaging device in the case where polysilicon is adopted as a filler.

FIG. 4 is a diagram illustrating the structure of a section of a solid-state imaging device in which a trench portion of a first pixel separating portion passes through a substrate.

FIG. 5 is a diagram illustrating the structure of a section of a solid-state imaging device in which a first pixel separating portion has no trench portion.

FIG. 6A is a diagram illustrating a method for manufacturing the solid-state imaging device, illustrating processes of forming n-type semiconductor regions, second groove portions, and first trench portions.

FIG. 6B is a diagram illustrating the structure of a section of a substrate taken along line D-D in FIG. 6A.

FIG. 7 is a diagram illustrating the method for manufacturing the solid-state imaging device, illustrating a process of forming semiconductor regions of an opposite conductivity type.

FIG. 8A is a diagram illustrating the method for manufacturing the solid-state imaging device, illustrating a process of forming FD portions, transfer gate electrodes, and ground electrodes.

FIG. 8B is a diagram illustrating the planar structure of the substrate in the case where FIG. 8A is viewed from the front side of the substrate.

FIG. 9 is a diagram illustrating the method for manufacturing the solid-state imaging device, illustrating a process of forming a wiring layer, a process of joining the wiring layer to a logic circuit board, and a process of thinning the substrate.

FIG. 10A is a diagram illustrating the method for manufacturing the solid-state imaging device, illustrating a process of forming first groove portions.

FIG. 10B is a diagram illustrating the planar structure of the substrate in the case where FIG. 10A is viewed from the front side of the substrate.

FIG. 11 is a diagram illustrating the method for manufacturing the solid-state imaging device, illustrating the process of forming the first groove portions.

FIG. 12 is a diagram illustrating the method for manufacturing the solid-state imaging device, illustrating a process of forming a pinning film and an insulating film.

FIG. 13 is a diagram illustrating the structure of a section of a solid-state imaging device according to an example modification (1).

FIG. 14 is a diagram illustrating the structure of a section of a solid-state imaging device according to an example modification (2).

FIG. 15 is a diagram illustrating the structure of a section of a solid-state imaging device according to an example modification (3).

FIG. 16 is a diagram illustrating the structure of a section of a solid-state imaging device according to the example modification (3).

FIG. 17 is a diagram illustrating the structure of a section of a solid-state imaging device according to an example modification (4).

FIG. 18 is a diagram illustrating the structure of a section of a solid-state imaging device according to the example modification (4).

FIG. 19 is a diagram illustrating the structure of a section of a solid-state imaging device according to an example modification (5).

FIG. 20 is a diagram illustrating the circuit configuration of pixels of the solid-state imaging device illustrated in FIG. 19.

FIG. 21 is a diagram illustrating the structure of a section of a solid-state imaging device according to the example modification (5).

FIG. 22A is a diagram illustrating the structure of a section of a solid-state imaging device according to the example modification (5).

FIG. 22B is a diagram illustrating the structure of a section of a solid-state imaging device according to the example modification (5).

FIG. 23 is a diagram illustrating the structure of a section of a solid-state imaging device according to an example modification (6).

FIG. 24A is a diagram illustrating a method for manufacturing the solid-state imaging device illustrated in FIG. 23.

FIG. 24B is a diagram illustrating the planar structure of a substrate in the case where FIG. 24A is viewed from the front side of the substrate.

FIG. 25A is a diagram illustrating the structure of a section of a solid-state imaging device according to an example modification (7).

FIG. 25B is a diagram illustrating the structure of a section of a substrate taken along line E-E in FIG. 25A.

FIG. 26 is a diagram illustrating the structure of a section of a solid-state imaging device according to the example modification (7).

FIG. 27A is a diagram illustrating the structure of a section of a solid-state imaging device according to the example modification (7).

FIG. 27B is a diagram illustrating the structure of a section of a substrate taken along line F-F in FIG. 27A.

FIG. 28 is a diagram illustrating the structure of a section of a solid-state imaging device according to an example modification (8).

FIG. 29 is a diagram illustrating the structure of a section of a solid-state imaging device according to the example modification (8).

FIG. 30 is a diagram illustrating the structure of a section of a solid-state imaging device according to the example modification (8).

FIG. 31 is a diagram illustrating the structure of a section of a solid-state imaging device according to an example modification (9) taken along a position corresponding to line B-B in FIG. 3A.

FIG. 32 is a diagram illustrating the structure of a section of a solid-state imaging device according to the example modification (9) taken along a position corresponding to line B-B in FIG. 3A.

FIG. 33 is a diagram illustrating the structure of a section of a solid-state imaging device according to an example modification (10) taken along a position corresponding to line C-C in FIG. 3A.

FIG. 34 is a diagram illustrating the structure of a section of a solid-state imaging device according to the example modification (10) taken along a position corresponding to line C-C in FIG. 3A.

FIG. 35 is a diagram illustrating the structure of a section of a solid-state imaging device according to the example modification (10) taken along a position corresponding to line C-C in FIG. 3A.

FIG. 36 is a diagram illustrating the structure of a section of a solid-state imaging device according to the example modification (10) taken along a position corresponding to line C-C in FIG. 3A.

FIG. 37 is a diagram illustrating the structure of a section of a solid-state imaging device according to the example modification (10) taken along a position corresponding to line C-C in FIG. 3A.

FIG. 38 is a diagram illustrating the structure of a section of a solid-state imaging device according to the example modification (10) taken along a position corresponding to line C-C in FIG. 3A.

FIG. 39 is a diagram illustrating the structure of a section of a solid-state imaging device according to the example modification (10) taken along a position corresponding to line C-C in FIG. 3A.

FIG. 40 is a diagram illustrating the structure of a section of a solid-state imaging device according to an example modification (11) taken along a position corresponding to line C-C in FIG. 3A.

FIG. 41 is a diagram illustrating the structure of a section of a solid-state imaging device according to the example modification (11) taken along a position corresponding to line C-C in FIG. 3A.

FIG. 42 is a diagram illustrating the structure of a section of a solid-state imaging device according to the example modification (11) taken along a position corresponding to line C-C in FIG. 3A.

FIG. 43 is a diagram illustrating the planar structure of a solid-state imaging device according to an example modification (12) when viewed from the side on which a microlens layer lies.

FIG. 44 is a diagram illustrating the planar structure of a solid-state imaging device according to the example modification (12) when viewed from the side on which a microlens layer lies.

FIG. 45 is a diagram illustrating the planar structure of a solid-state imaging device according to the example modification (12) when viewed from the side on which a microlens layer lies.

FIG. 46 is a schematic configuration diagram of an electronic device according to a second embodiment.

### DESCRIPTION OF EMBODIMENTS

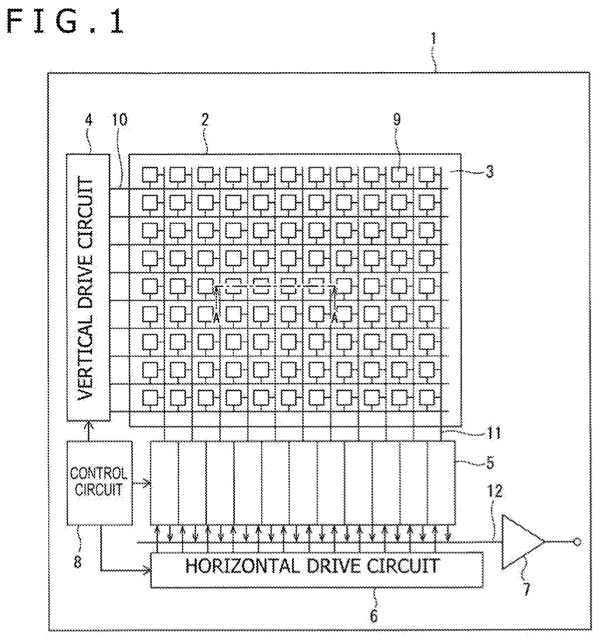

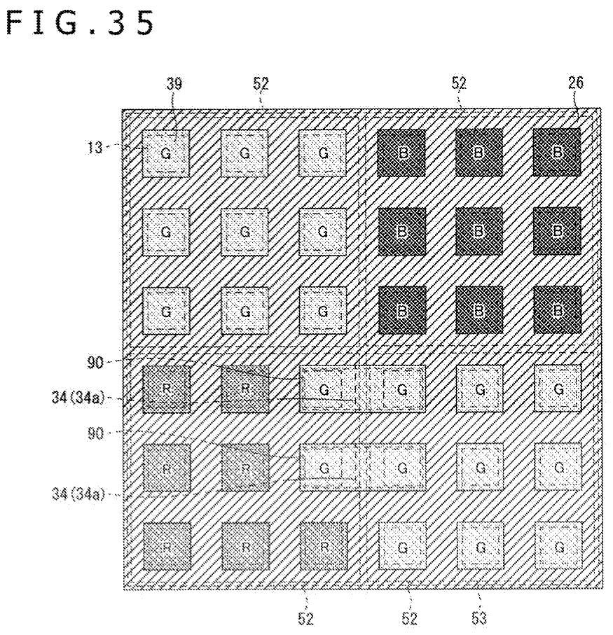

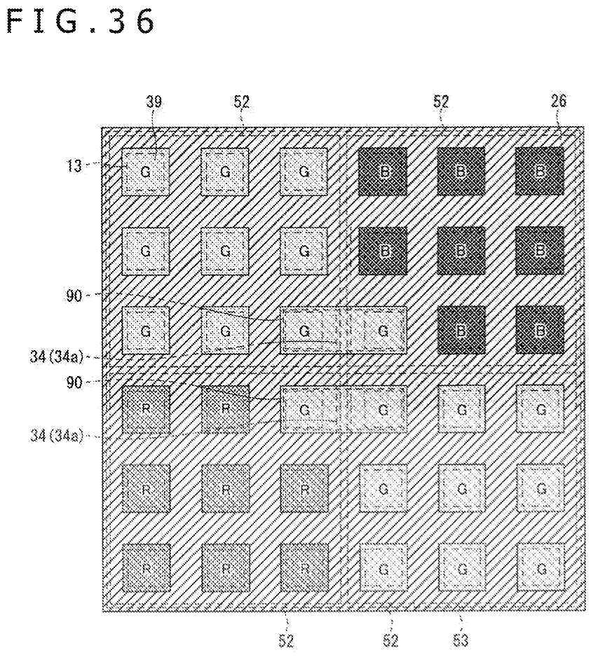

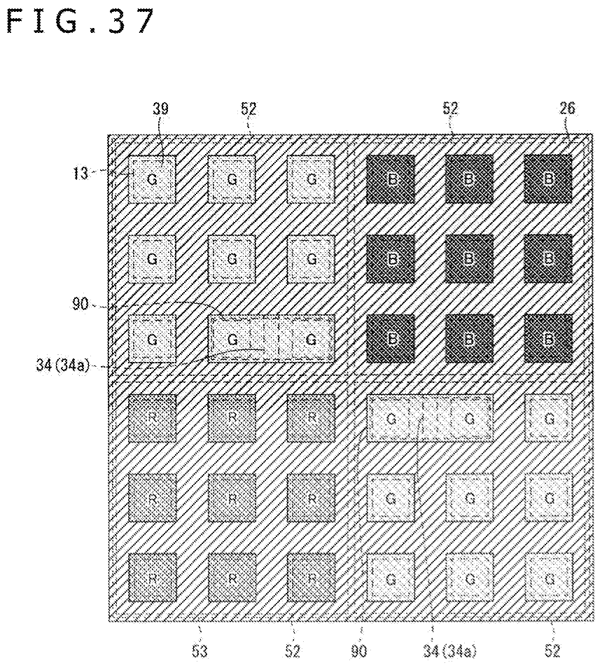

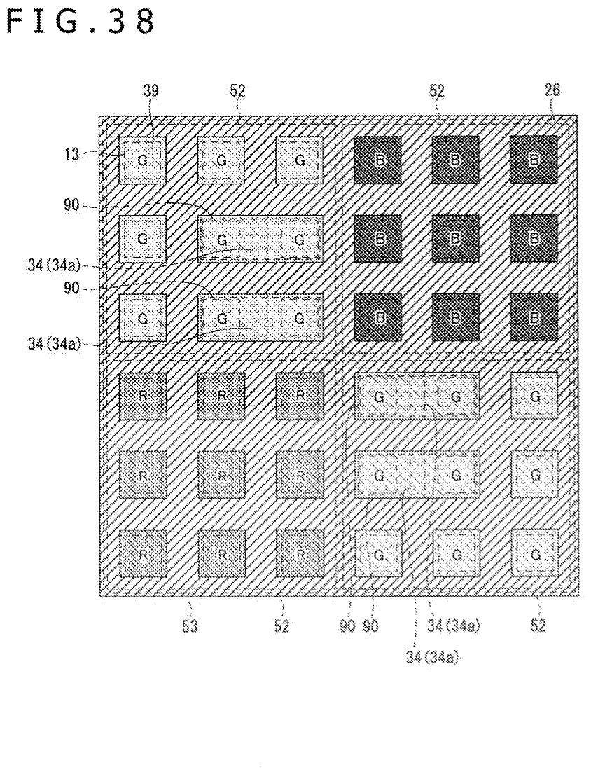

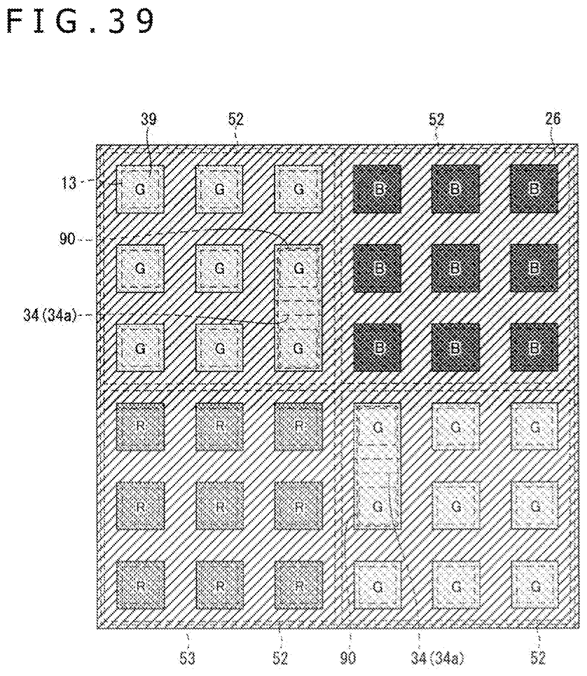

Hereinafter, examples of photodetection devices and electronic devices according to embodiments of the present disclosure will be described with reference to FIGS. 1 to 46. The embodiments of the present disclosure will be described in the following order. Note that the present disclosure is not limited to the examples described below. Also note that advantageous effects mentioned in the present specification are illustrative and not restrictive, and there may be other advantageous effects.
1. First embodiment: solid-state imaging device
   1-1 Overall structure of solid-state imaging device
   1-2 Circuit configuration of pixels
   1-3 Structure of important portions
   1-4 Method for manufacturing solid-state imaging device
   1-5 Example modifications
2. Second embodiment: example of application to electronic device

### 1. First Embodiment: Solid-State Imaging Device

### 1-1 Overall Structure of Solid-State Imaging Device

A solid-state imaging device 1 (a “photodetection device” in a broad sense) according to a first embodiment of the present disclosure will be described below. FIG. 1 is a schematic configuration diagram illustrating a whole of the solid-state imaging device 1 according to the first embodiment.

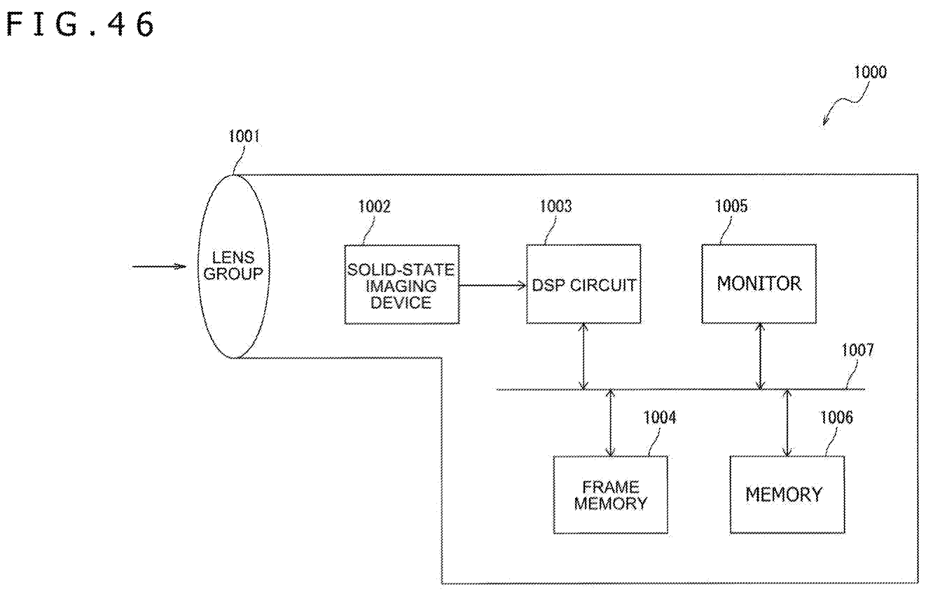

The solid-state imaging device 1 in FIG. 1 is a back-illuminated CMOS (Complementary Metal Oxide Semiconductor) image sensor. As illustrated in FIG. 46, the solid-state imaging device 1 (1002) takes image-forming light (i.e., incident light) coming from a subject through a lens group 1001, converts the amounts of incident light forming an image on an imaging surface to electrical signals on a pixel-by-pixel basis, and outputs the electrical signals as pixel signals.

As illustrated in FIG. 1, the solid-state imaging device 1 includes a substrate 2, a pixel region 3, a vertical drive circuit 4, column signal processing circuits 5, a horizontal drive circuit 6, an output circuit 7, and a control circuit 8.

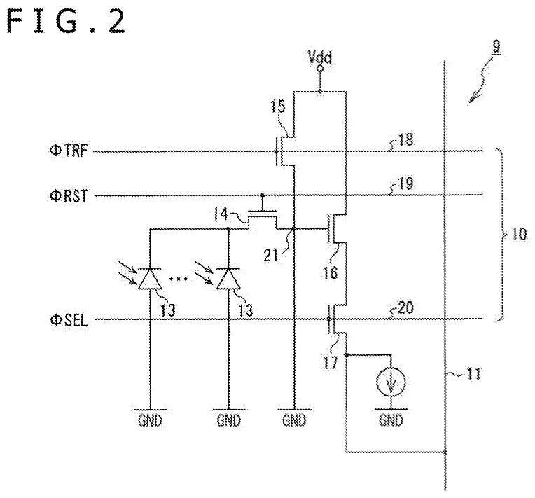

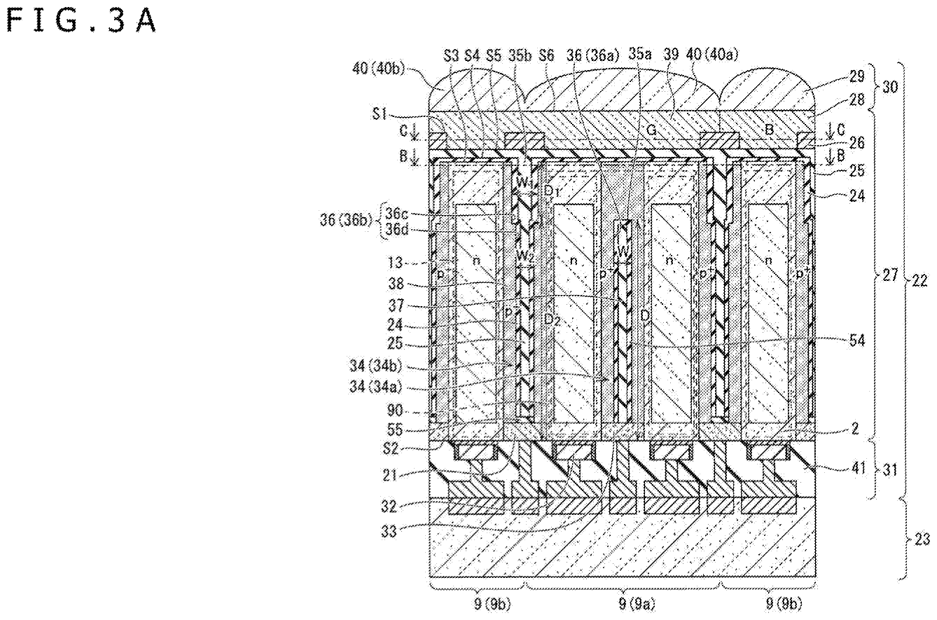

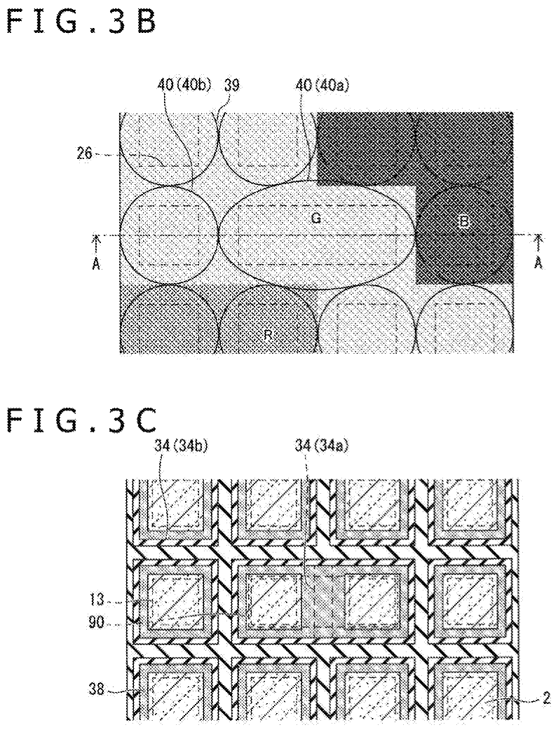

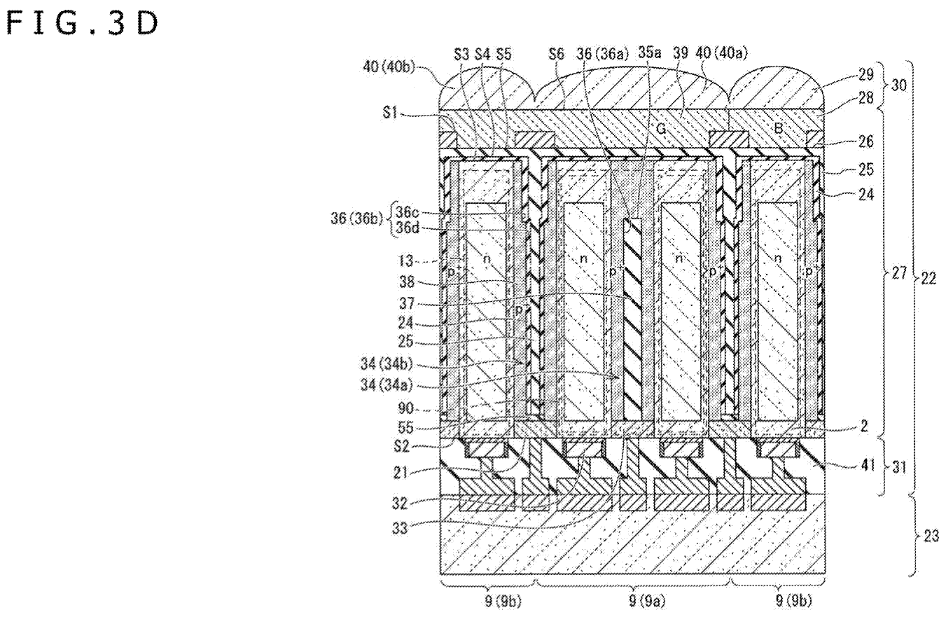

The pixel region 3 has multiple pixels 9 systematically arranged in a two-dimensional array on the substrate 2. Each pixel 9 includes multiple pixel transistors and a photoelectric conversion part 13 as illustrated in FIGS. 2, 3A, and 3C. As the multiple pixel transistors, for example, four transistors, including a transfer transistor 14, a reset transistor 15, an amplification transistor 16, and a selection transistor 17, can be adopted. Alternatively, the transfer transistor 14, the reset transistor 15, and the amplification transistor 16, excluding the selection transistor 17, may be adopted, for example. The pixel transistors may have, for example, VirticalGate, FinGate, plane Gate, or other structures.

In addition, as illustrated in FIG. 3A, the pixels 9 include phase difference pixels 9a and normal pixels 9b. The phase difference pixels 9a are pixels for generating pixel signals used to compute phase difference information for controlling an image-surface phase difference AF (Auto Focus) function. With respect to the phase difference pixels 9a, a microlens 40 is formed for each of sets of adjacent ones of the phase difference pixels 9a. In other words, for the phase difference pixels 9a, shared-type microlenses 40 (also denoted by “40a”) are provided each of which is formed for a separate one of photoelectric conversion part groups 90 each including the photoelectric conversion parts 13 included in adjacent ones of the phase difference pixels 9a. FIG. 3A illustrates an example case where each photoelectric conversion part group 90 includes 2×1, i.e., two, adjacent ones of the photoelectric conversion parts 13. The normal pixels 9b are pixels for generating pixel signals of images. With respect to the normal pixels 9b, a microlens 40 is formed for each of the normal pixels 9b. In other words, for the normal pixels 9b, individual microlenses 40 (also denoted by “40b”) are provided each of which is formed for a separate one of the photoelectric conversion parts 13 included in the normal pixels 9b.

The vertical drive circuit 4, which is formed by, for example, a shift register, selects a desired pixel drive wire 10, and supplies a pulse for driving the pixels 9 to the selected pixel drive wire 10, thereby driving the pixels 9 on a row-by-row basis. That is, the vertical drive circuit 4 scans and selects the pixels 9 in the pixel region 3 on a row-by-row basis sequentially in a vertical direction, and supplies, to the column signal processing circuits 5 through vertical signal lines 11, pixel signals based on signal charges generated in the photoelectric conversion parts 13 of the pixels 9 according to the amounts of light received.

The column signal processing circuits 5 are each disposed for a separate column of pixels 9, for example, and perform signal processing, such as noise reduction, on the signals outputted from a row of pixels 9 on a pixel line by pixel line basis. The column signal processing circuits 5 perform signal processing such as CDS (Correlated Double Sampling) for removing fixed-pattern noise specific to the pixels and AD (Analog Digital) conversion, for example.

The horizontal drive circuit 6, which is formed by, for example, a shift register, outputs horizontal scanning pulses to the column signal processing circuits 5 sequentially, thereby selecting the column signal processing circuits 5 one after another to cause each of the column signal processing circuits 5 to output the pixel signal subjected to the signal processing to a horizontal signal line 12.

The output circuit 7 performs signal processing on the pixel signals supplied sequentially from each of the column signal processing circuits 5 through the horizontal signal line 12, and outputs the resulting pixel signals. Examples of this signal processing include buffering, black level adjustment, column variation correction, and various types of digital signal processing.

The control circuit 8 generates control signals and clock signals on the basis of which the vertical drive circuit 4, the column signal processing circuits 5, the horizontal drive circuit 6, and so on operate, on the basis of a vertical synchronization signal, a horizontal synchronization signal, and a master clock signal. Then, the control circuit 8 outputs the generated control signals and clock signals to the vertical drive circuit 4, the column signal processing circuits 5, the horizontal drive circuit 6, and so on.

### 1-2 Circuit Configuration of Pixels

Next, the circuit configuration of the pixels 9 illustrated in FIG. 1 will now be described below. FIG. 2 is a diagram illustrating the circuit configuration of the pixels 9. As illustrated in FIG. 2, each pixel 9 has the photoelectric conversion part 13 and four pixel transistors (i.e., the transfer transistor 14, the reset transistor 15, the amplification transistor 16, and the selection transistor 17). Note that FIG. 2 illustrates an example case where the pixel transistors are shared by multiple pixels 9 (photoelectric conversion parts 13). N-channel MOS transistors, for example, can be adopted as the transfer transistor 14, the reset transistor 15, the amplification transistor 16, and the selection transistor 17. In addition, as pixel drive wires 10 for the pixels 9, three drive wires, including a transfer line 18, a reset line 19, and a selection line 20, for example, are provided for and shared by the pixels 9 in the same row. One end of each of the transfer line 18, the reset line 19, and the selection line 20 is connected to an output terminal of the vertical drive circuit 4 corresponding to the corresponding row on a row-by-row basis.

Each photoelectric conversion part 13 has an anode electrode connected to a ground, and a cathode electrode connected to a gate electrode of the amplification transistor 16 through the transfer transistor 14. Then, the photoelectric conversion part 13 generates a signal charge according to the amount of incident light. A node connected to the gate electrode of the amplification transistor 16 is referred to as an FD portion (floating diffusion portion) 21.

The transfer transistor 14 is connected between the cathode electrode of the photoelectric conversion part 13 and the FD portion 21. A transfer pulse φTRF, which is active when being at a high level (e.g., Vdd) (also called “High-active,” hereinafter), is supplied to a gate electrode of the transfer transistor 14 via the transfer line 18. The supply of the transfer pulse φTRF causes the transfer transistor 14 to enter an ON state to transfer the signal charge generated in the photoelectric conversion part 13 to the FD portion 21.

The reset transistor 15 has a drain electrode connected to a pixel power supply Vdd, and a source electrode connected to the FD portion 21. Prior to the transfer of the signal charge from the photoelectric conversion part 13 to the FD portion 21 through the transfer transistor 14, a reset pulse PRST, which is high-active, is supplied to a gate electrode of the reset transistor 15 via the reset line 19. The supply of the reset pulse φRST causes the reset transistor 15 to enter an ON state to reset the FD portion 21 with electric charge accumulated in the FD portion 21 discarded to the pixel power supply Vdd.

The amplification transistor 16 has the gate electrode connected to the FD portion 21, and a drain electrode connected to the pixel power supply Vdd. In addition, the amplification transistor 16 outputs, as a reset signal (reset level) Vreset, a potential of the FD portion 21 reset by the reset transistor 15. Moreover, the amplification transistor 16 outputs, as a light accumulation signal (signal level) Vsig, a potential of the FD portion 21 after the transfer of the signal charge by the transfer transistor 14.

The selection transistor 17 has a drain electrode connected to a source electrode of the amplification transistor 16, and a source electrode connected to the corresponding vertical signal line 11. A selection pulse φSEL, which is high-active, is supplied to a gate electrode of the selection transistor 17 via the selection line 20. The supply of the selection pulse φSEL causes the selection transistor 17 to enter an ON state to cause the corresponding pixel(s) 9 to be in a selected state and relay signals outputted from the amplification transistor 16 to the corresponding vertical signal line 11.

### 1-3 Structure of Important Portions

Next, the detailed structure of the solid-state imaging device 1 in FIG. 1 will now be described below. FIG. 3A is a diagram illustrating the structure of a section of the solid-state imaging device 1 taken along line A-A in FIG. 1. FIG. 3B is a diagram illustrating the planar structure of the solid-state imaging device 1 in the case where FIG. 3A is viewed from the side on which a microlens layer 29 lies. Meanwhile, FIG. 3C is a diagram illustrating the structure of a section of the solid-state imaging device 1 taken along line B-B in FIG. 3A.

As illustrated in FIG. 3A, the solid-state imaging device 1 includes an image sensor board 22 and a logic circuit board 23 joined to the image sensor board 22, and having the vertical drive circuit 4, the column signal processing circuits 5, the horizontal drive circuit 6, the output circuit 7, and the control circuit 8 illustrated in FIG. 1.

The image sensor board 22 has arranged therein a light reception layer 27 including the substrate 2, a pinning film 24, an insulating film 25, and a light-shielding film 26 layered in the order named. In addition, a light condensation layer 30 including a color filter layer 28 and the microlens layer 29 layered in the order named is arranged on a surface (hereinafter referred to also as a “rear surface S1”) of the light reception layer 27 on the side on which the light-shielding film 26 lies. Further, a wiring layer 31 is arranged on a surface (hereinafter referred to also as a “front surface S2”) of the light reception layer 27 on the side on which the substrate 2 lies.

The substrate 2 is formed by, for example, a semiconductor substrate including silicon (Si), and forms the pixel region 3. Multiple pixels 9 each having the photoelectric conversion part 13 and the four pixel transistors, i.e., the transfer transistor 14, the reset transistor 15, the amplification transistor 16, and the selection transistor 17, are arranged in a two-dimensional array in the pixel region 3. Each photoelectric conversion part 13 includes a p-type semiconductor region formed on the side closer to the front surface S2 of the substrate 2, and an n-type semiconductor region formed on the side closer to a rear surface S3 thereof (i.e., the side closer to the light receiving surface), and forms a photodiode through pn junction. Thus, each of the photoelectric conversion parts 13 generates a signal charge according to the amount of light incident on the photoelectric conversion part 13, and accumulates the generated signal charge in the n-type semiconductor region (i.e., a charge accumulation region).

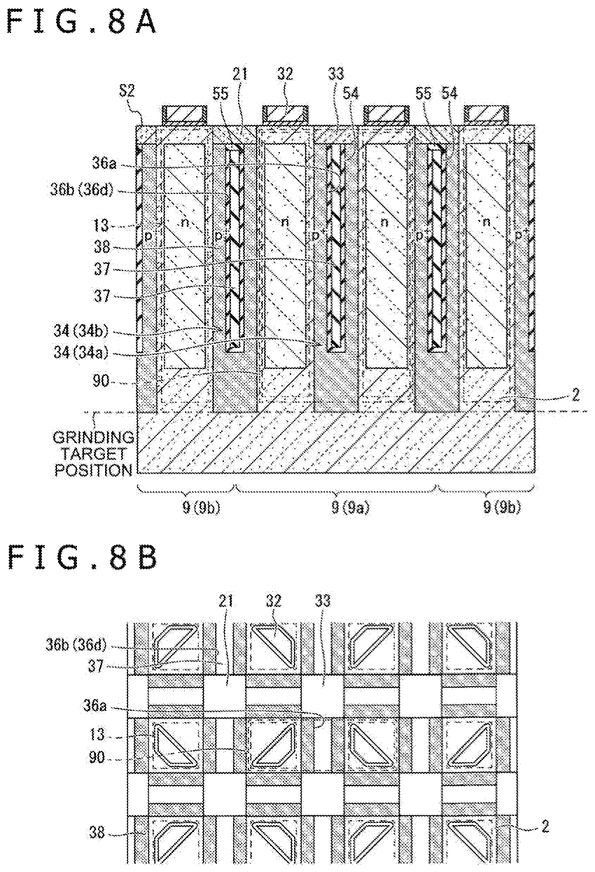

In addition, the transfer transistor 14 has the FD portion 21 and a transfer gate electrode 32. The FD portion 21 is formed at a position between the wiring layer 31 and a bottom surface of a trench portion 36 of a second pixel separating portion 34b in the substrate 2 in a side view of a section thereof perpendicular to the rear surface S3 of the substrate 2 (see FIG. 3A), and at an intersection of pixel separating portions 34 in a plan view of a section thereof parallel to the rear surface S3 (see FIG. 8B). Meanwhile, the transfer gate electrode 32 is formed at a position between a wire in the wiring layer 31 and the photoelectric conversion part 13 (i.e., the substrate 2) in the side view (see FIG. 3A), and at a position overlapping with the photoelectric conversion part 13 in the plan view (see FIG. 8B). In addition, similarly, a ground electrode 33, which is electrically connected to a filler 37 buried in an interior of a trench portion 36 of a first pixel separating portion 34a, is formed at a position between the wiring layer 31 and a bottom surface of the trench portion 36 of the first pixel separating portion 34a in the substrate 2 in the side view (see FIG. 3A), and at an intersection of pixel separating portions 34 in the plan view (see FIG. 8B).

In addition, the pixel separating portions 34 are formed between adjacent ones of the photoelectric conversion parts 13. The pixel separating portions 34 are formed in a grid pattern so as to surround each of the photoelectric conversion parts 13 when viewed from the side on which the microlens layer 29 lies. The pixel separating portions 34 include first pixel separating portions 34a arranged between at least some of the photoelectric conversion parts 13 in each photoelectric conversion part group 90, and second pixel separating portions 34b arranged between the photoelectric conversion parts 13 where none of the first pixel separating portions 34a is arranged. FIGS. 3A and 3C illustrate an example case where the first pixel separating portions 34a are arranged between every adjacent ones of the photoelectric conversion parts 13 in each photoelectric conversion part group 90, while the second pixel separating portions 34b are arranged between the photoelectric conversion parts 13 included in adjacent ones of the normal pixels 9b and between some of the photoelectric conversion parts 13 included in the normal pixels 9b and some of the photoelectric conversion parts 13 in the photoelectric conversion part groups 90 which are adjacent to the some photoelectric conversion parts 13.

In addition, as illustrated in FIG. 3A, an end portion 35a of each first pixel separating portion 34a on the side closer to the rear surface S3 is positioned on the side of the rear surface S3 of the substrate 2 closer to the front surface S2 (i.e., on the side thereof closer to a surface opposite to the light receiving surface). In addition, an end portion 35b of each second pixel separating portion 34b on the side closer to the rear surface S3 is positioned closer to the rear surface S3 of the substrate 2 than is the end portion 35a of the first pixel separating portion 34a on the side closer to the rear surface S3. FIG. 3A illustrates an example case where the end portion 35b of the second pixel separating portion 34b is flush with the rear surface S3 of the substrate 2.

The first pixel separating portions 34a and the second pixel separating portions 34b have trench portions 36. The trench portions 36 are formed in a grid pattern such that inside surfaces thereof define contours of the pixel separating portions 34. The trench portion 36 (hereinafter referred to also as a “first trench portion 36a”) of each first pixel separating portion 34a is formed by a groove portion that has a uniform groove width W in a section perpendicular to the rear surface S3 of the substrate 2. The first trench portion 36a has a mouth portion at the front surface S2 (i.e., the surface opposite to the light receiving surface) of the substrate 2, has a bottom surface on the side closer to the rear surface S3, and extends in a direction perpendicular to the rear surface S3 of the substrate 2.

Meanwhile, the trench portion 36 (hereinafter referred to also as a “second trench portion 36b”) of each second pixel separating portion 34b is formed by two groove portions (hereinafter referred to also as a “first groove portion 36c” and a “second groove portion 36d”) that have different groove widths W₁ and W₂ in a section perpendicular to the rear surface S3 of the substrate 2. The first groove portion 36c is a groove portion that has a mouth portion at the rear surface S3 of the substrate 2, and which extends in the direction perpendicular to the rear surface S3 of the substrate 2. Meanwhile, the second groove portion 36d is a groove portion that has mouth portions at a bottom surface of the first groove portion 36c and at the front surface S2 of the substrate 2, and which extends in the direction perpendicular to the rear surface S3 of the substrate 2. Thus, the second trench portion 36b has mouth portions at the rear surface S3 and the front surface S2 of the substrate 2, and extends in the direction perpendicular to the rear surface S3 of the substrate 2 and passes through the substrate 2. FIG. 3A illustrates an example case where the width W₁ of the first groove portion 36c is greater than the width W₂ of the second groove portion 36d. The relationship W₁>W₂ allows the volume of the photoelectric conversion parts 13 to be greater than in the case where W₁<W₂.

In addition, the width W₂ of the second groove portion 36d is equal to the width W of the first trench portion 36a. Moreover, in a section perpendicular to the rear surface S3 of the substrate 2, the depth D₂ of the second groove portion 36d is equal to the depth D of the first trench portion 36a. That is, a cross section of the second groove portion 36d and a cross section of the first trench portion 36a are formed in the same shape of a rectangle. Furthermore, the depth D₁ of the second groove portion 36d is smaller than the depth D₂ of the second groove portion 36d.

In addition, the filler 37 is buried in an interior of the first trench portion 36a. As the filler 37, a material that can be removed by a wet etching technique, for example, can be adopted. Examples thereof include polysilicon (poly-Si), a silicon oxide (SiO₂), and a silicon nitride (Si₃N₄). Note that an oxide film 54 may be formed between bulk silicon (i.e., inside surfaces of the first trench portion 36a) and polysilicon (i.e., the filler 37). For example, in the case where polysilicon is adopted as the filler 37, the oxide film 54 will ensure sufficient selectivity of the filler 37 to bulk silicon (i.e., the inside surfaces of the first trench portion 36a). The oxide film 54 may be omitted as illustrated in FIG. 3D.

In addition, inside surfaces of the second trench portion 36b (i.e., the first groove portion 36c and the second groove portion 36d) are covered with the pinning film 24. This contributes to suppressing an interface state of a side surface of the second pixel separating portion 34b. Moreover, the insulating film 25 is buried in an interior of the second trench portion 36b. This allows light incident on the pixels 9 adjacent to the second trench portion 36b to be reflected by an interface between the second trench portion 36b and the substrate 2, which contributes to suppressing optical color mixing at the normal pixels 9b. Furthermore, a stopper film 55, which functions as an etching stopper in a process of forming the second pixel separating portion 34b, is formed in a portion of the interior of the second trench portion 36b which is on the side closer to the front surface S2 of the substrate 2. As a material of the stopper film 55, a silicon oxide (SiO₂) or a silicon nitride (SiN) can be adopted, for example, in the case where the filler 37 is polysilicon.

In addition, between each photoelectric conversion part 13 and the pixel separating portions 34 (34a, 34b), a semiconductor region 38 of a conductivity type (i.e., a p-type) opposite to that of the charge accumulation region (i.e., the n-type semiconductor region) of the photoelectric conversion part 13 is provided so as to surround the photoelectric conversion part 13. Boron (B), for example, can be adopted as a p-type impurity that forms the semiconductor region 38 of the opposite conductivity type (i.e., the p-type). This contributes to strengthening pinning (i.e., creating a state of a high hole concentration) at an interface between the photoelectric conversion part 13 and the pixel separating portions 34 (34a, 34b), which contributes to suppressing occurrence of dark current.

The pinning film 24 covers the whole rear surface S3 of the substrate 2 and the inside surfaces of each second trench portion 36b (i.e., the first groove portion 36c and the second groove portion 36d) continuously. As a material of the pinning film 24, a high dielectric film or a high refractive index material film having negative charges capable of strengthening pinning by generating fixed charges when accumulated on the substrate 2, for example, can be adopted. Examples thereof include a nitride or oxide including at least one element among hafnium (Hf), aluminum (Al), zirconium (Zr), tantalum (Ta), and titanium (Ti).

The insulating film 25 is buried in the interior of each second trench portion 36b, and covers a whole rear surface S4 of the pinning film 24 continuously. As a material of the insulating film 25, an oxide film having a refractive index different from that of the substrate 2 (Si), for example, can be adopted. Examples of the oxide film include a silicon oxide (SiO₂), a silicon nitride (Si₃N₄), and a silicon oxynitride (SiON).

The light-shielding film 26 is formed in a grid pattern on a portion of a rear surface S5 of the insulating film 25 so as to make a light receiving surface of each photoelectric conversion part 13 open. That is, the light-shielding film 26 is formed over a region that overlaps with the pixel separating portions 34 formed in a grid pattern when viewed from the side on which the microlens layer 29 lies. Note, however, that the light-shielding film 26 is not formed over a region that overlaps with each of the first pixel separating portions 34a out of the pixel separating portions 34. As a material of the light-shielding film 26, a material capable of light shielding, for example, can be adopted. Examples thereof include a metal, alloy, oxide, or nitride including at least one element among aluminum (Al), tungsten (W), copper (Cu), and titanium (Ti).

The color filter layer 28 is formed on the rear surface S5 of the insulating film 25 and includes multiple color filters 39 arranged so as to correspond to the photoelectric conversion parts 13 and the photoelectric conversion part groups 90. Specifically, with respect to the normal pixels 9b, one color filter 39 is formed for one photoelectric conversion part 13. Meanwhile, with respect to the phase difference pixels 9a, one color filter 39 is formed for one photoelectric conversion part group 90. The multiple color filters 39 include multiple types of color filters that allow light of specific wavelengths included in light collected and condensed by the microlenses 40 to pass therethrough. Examples thereof include an R filter, which allows red light to pass therethrough, a G filter, which allows green light to pass therethrough, and a B filter, which allows blue light to pass therethrough. Thus, each of the multiple color filters 39 allows light of specific wavelengths to pass therethrough to allow the light, passing therethrough, to enter into the corresponding photoelectric conversion part 13 or photoelectric conversion part group 90.

As an array pattern of the color filters 39, a Quad-Bayer array, for example, can be adopted which is modified such that, out of four color filters that allow blue light to pass therethrough, a color filter that is adjacent to color filters that allow green light to pass therethrough and a color filter that allows red light to pass therethrough is substituted with a color filter that allows green light to pass therethrough. FIG. 3B illustrates an example case where a substituting color filter for two pixels that allows green light to pass therethrough is used as the color filter 39 for the phase difference pixels 9a.

In addition, examples of the color filters 39 include filters including a multilayer film having low-refractivity layers and high refractive index layers laminated alternately, filters including multiple nanostructures having dimensions smaller than the wavelengths of light that the color filters 39 allow to pass therethrough, filters including a colored resin film including a resin material and having a coloring agent dispersed therein, and any combinations of these filters. Examples of the filters including a multilayer film include a structural color filter using multilayer film interference (in other words, a photonic liquid crystal filter, a filter including a dielectric multilayer film). In addition, examples of the filters including multiple nanostructures include a structural color filter using guided-mode resonance or surface plasmon resonance (in other words, a metamaterial filter). Further, examples of the filters including a colored resin film include a filter including a color resist.

The microlens layer 29 is formed on a rear surface S6 of the color filter layer 28 and includes multiple microlenses 40 arranged so as to correspond to the photoelectric conversion parts 13 and the photoelectric conversion part groups 90. Specifically, with respect to the normal pixels 9b, one microlens 40 (individual-type microlens 40b) is formed for one photoelectric conversion part 13. Meanwhile, with respect to the phase difference pixels 9a, one microlens 40 (shared-type microlens 40a) is formed for one photoelectric conversion part group 90. In other words, the microlenses 40 include individual-type microlenses 40b each formed for a separate one of the photoelectric conversion parts 13 included in the normal pixels 9b, and shared-type microlenses 40a each formed for a separate one of the photoelectric conversion part groups 90 each including the photoelectric conversion parts 13 included in adjacent ones of the phase difference pixels 9a. Thus, each of the multiple microlenses 40 collects and condenses image-forming light (i.e., incident light) from a subject, and allows the collected and condensed incident light to efficiently enter into the corresponding photoelectric conversion part 13 or photoelectric conversion part group 90 through the corresponding color filter 39.

The wiring layer 31 is formed on the front surface S2 of the substrate 2 and includes an interlayer insulating film 41 and wires (not illustrated) arranged in multiple layers with the interlayer insulating film 41 intervening therebetween. Then, the wiring layer 31 drives the pixel transistors of each pixel 9 through the wires in the multiple layers.

In the solid-state imaging device 1 having the above-described structure, light is applied from the side on which the rear surface S3 of the substrate 2 lies, the applied light passes through the microlenses 40 and the color filters 39, and the light, passing therethrough, is subjected to photoelectric conversion in the photoelectric conversion parts 13, so that signal charges are generated. Then, the generated signal charges are outputted, as pixel signals, by the vertical signal lines 11 illustrated in FIG. 1, which are formed by wires in the wiring layer 31, through the pixel transistors formed on the side on which the front surface S2 of the substrate 2 lies. In addition, the phase difference information is computed on the basis of the pixel signals outputted from the photoelectric conversion parts 13 of the phase difference pixels 9a to perform focus control.

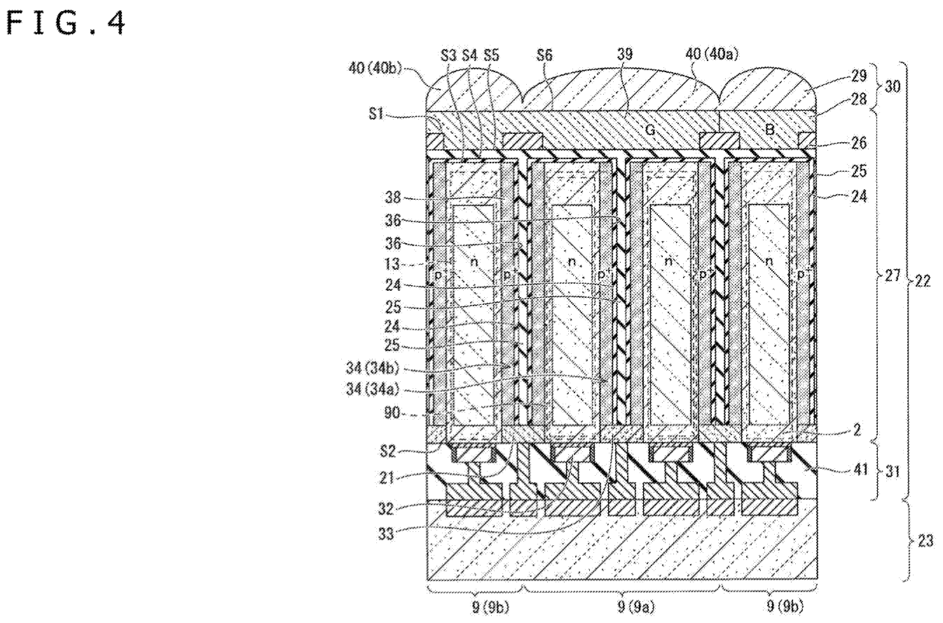

Here, in the case where, as illustrated in FIG. 4, separating structures (i.e., pixel separating portions 34) each having a trench portion 36 passing through the substrate 2 from the rear surface S3 (i.e., the light receiving surface) to the front surface S2 (i.e., the surface on the opposite side) are used as the first pixel separating portions 34a and the second pixel separating portions 34b, for example, incident light impinging on a surface, on the side closer to the microlenses 40, of the pixel separating portion 34 at any phase difference pixels 9a may cause the incident light to be scattered at the pixel separating portion 34, which may result in a reduction in the sensitivity ratio (i.e., information about a difference in sensitivity between left and right pixels) of the phase difference pixels 9a. In addition, if incident light traveling obliquely impinges on a side surface of the pixel separating portion 34 at any phase difference pixels 9a, for example, the incident light may be reflected by the pixel separating portion 34 to be guided toward a photoelectric conversion part 13 different from the photoelectric conversion part 13 toward which the incident light had been traveling, which may result in a reduction in the sensitivity ratio of the phase difference pixels 9a.

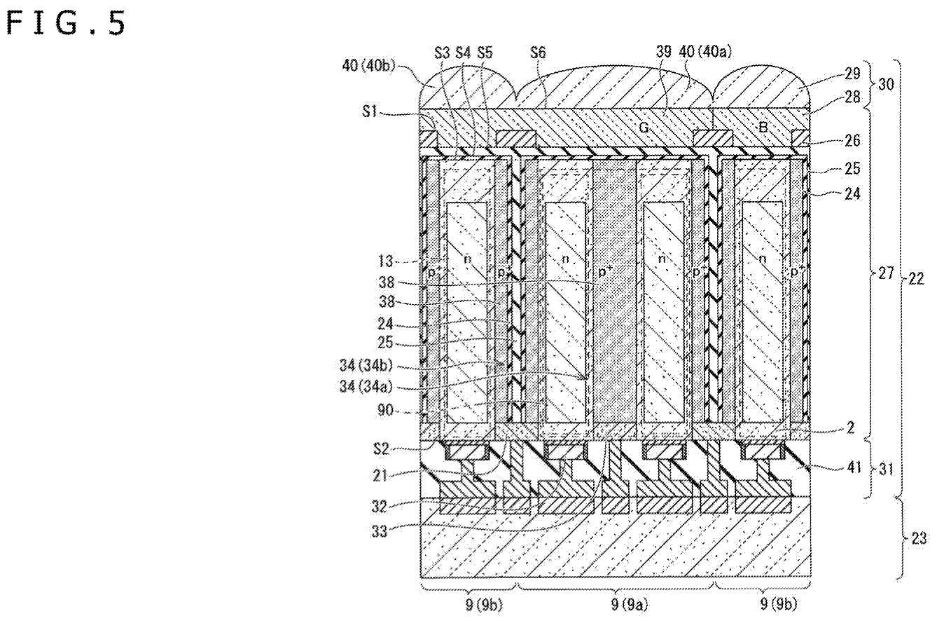

Further, in the case where, as illustrated in FIG. 5, the trench portion 36 between the phase difference pixels 9a is omitted, and a separating structure that separates the phase difference pixels 9a from each other with a gap between the phase difference pixels 9a being doped with an impurity is used, for example, different separating structures are formed for the normal pixels 9b and the phase difference pixels 9a, and it is necessary to make potential designs of the photoelectric conversion parts 13 separately for the normal pixels 9b and the phase difference pixels 9a and form the normal pixels 9b and the phase difference pixels 9a separately. This can make implementation difficult in terms of design and manufacture.

In contrast, in the first embodiment, as illustrated in FIG. 3A, the pixel separating portions 34 include the first pixel separating portions 34a arranged between at least some of the photoelectric conversion parts 13 (in FIG. 3A, between all of the photoelectric conversion parts 13) in each photoelectric conversion part group 90, and the second pixel separating portions 34b arranged between the photoelectric conversion parts 13 where none of the first pixel separating portions 34a is arranged. Moreover, the end portion 35a of each first pixel separating portion 34a on the side closer to the rear surface S3 (i.e., the side closer to the light receiving surface) is positioned on the side of the rear surface S3 (i.e., the light receiving surface) closer to the front surface S2 (i.e., on the side thereof closer to the surface opposite to the light receiving surface), while the end portion 35b of each second pixel separating portion 34b on the side closer to the rear surface S3 (i.e., the side closer to the light receiving surface) is positioned closer to the rear surface S3 than is the end portion 35a of the first pixel separating portion 34a on the side closer to the rear surface S3.

Thus, around each normal pixel 9b, the trench portions 36 (i.e., the second trench portions 36b) are formed so as to extend up to the rear surface S3 (i.e., the light receiving surface) of the substrate 2, and accordingly, light incident on the pixel 9 adjacent to each second trench portions 36b can be reflected by the interface between the second trench portion 36b and the substrate 2, which contributes to suppressing optical color mixing at the normal pixels 9b. In addition, around each phase difference pixel 9a, the trench portion 36 (i.e., the first trench portion 36a) is not formed so as to extend up to the rear surface S3 (i.e., the light receiving surface) of the substrate 2, and this contributes to reducing the likelihood that light incident on the phase difference pixel 9a will be scattered or guided by the first trench portion 36a between the phase difference pixels 9a, and enhancing the sensitivity ratio of the phase difference pixels 9a. Thus, suppression of the optical color mixing at the normal pixels 9b and an enhancement in the sensitivity ratio of the phase difference pixels 9a can both be achieved. In addition, the use of the pixel separating portion 34 (34a) having the trench portion 36 as the separating structure between the normal pixels 9 contributes to maintaining basic characteristics, such as shading and Qs.

In addition, in terms of design, the normal pixels 9b and the phase difference pixels 9a have the same structure, eliminating the need to make designs thereof separately, and can be designed with the number of design steps remaining unchanged. Moreover, in terms of manufacture, it is not necessary to make the normal pixels 9b and the phase difference pixels 9a differently, resulting in increased robustness against production variation, and leading to implementing the present structure without a significant increase in the number of processes.

### 1-4 Method for Manufacturing Solid-State Imaging Device

Next, a method for manufacturing the solid-state imaging device 1 will now be described below.

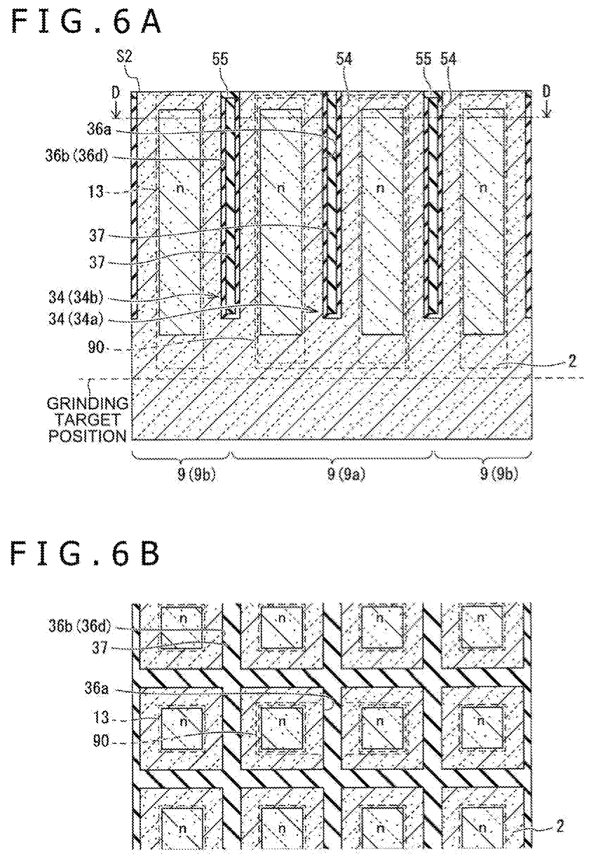

First, as illustrated in FIGS. 6A and 6B, the n-type semiconductor region of each photoelectric conversion part 13 is formed in the substrate 2, and thereafter, the first trench portions 36a and the second groove portions 36d of the second trench portions 36b are formed from the side on which the front surface S2 of the substrate 2 lies. Examples of a method for forming the n-type semiconductor region include adjustment using the substrate 2, ion implantation, sidewall diffusion, and a Doped-Epi (Epitaxial) substrate. Meanwhile, as a method for forming the first trench portions 36a and the second groove portions 36d, any of methods such as DTI (Deep Trench Isolation) and STI (Shallow Trench Isolation) can be adopted if separating gaps are formed. Examples include a method of performing anisotropic dry etching using a mask having opening portions at positions where the first trench portions 36a and the second groove portions 36d are to be formed. Each of the first trench portions 36a and the second groove portions 36d is arranged to have such a depth that the first trench portions 36a and the second groove portions 36d will not pass through the substrate 2 when the rear surface S3 of the substrate 2 is subjected to a grinding process.

Next, the oxide film 54 is formed on each of inner wall surfaces of the second groove portions 36d and the inside surfaces of the first trench portions 36a. Next, the filler 37 is buried in each of the interiors of the second groove portions 36d and the interiors of the first trench portions 36a to ensure flatness of the front surface S2 of the substrate 2. As a result, the first pixel separating portions 34a each having the first trench portion 36a and having the filler 37 buried in the interior thereof are formed. Note that the process of making the separating structures (i.e., the second groove portions 36d and the first trench portions 36a) may be performed before the process of forming the n-type semiconductor region. Next, the stopper film 55 is formed in a portion of an interior of the second groove portion 36d which is on the side closer to the front surface S2 of the substrate 2.

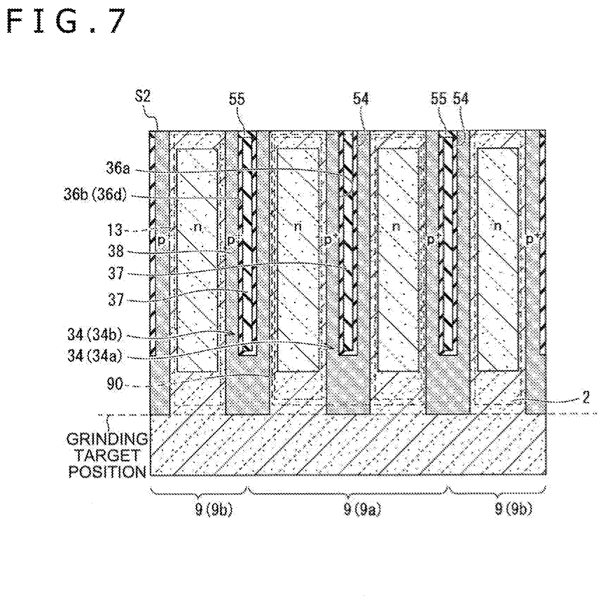

Next, as illustrated in FIG. 7, the semiconductor region 38 of the conductivity type (i.e., the p-type) opposite to that of the charge accumulation region of each photoelectric conversion part 13 is formed between adjacent ones of the photoelectric conversion parts 13 in the substrate 2 for pn junction and pinning. As a method for forming the semiconductor region 38 of the p-type, adjustment using the substrate 2, ion implantation, sidewall diffusion, or any combinations thereof, for example, can be adopted. Alternatively, a Doped-Epi substrate, for example, may be used. Next, as illustrated in FIGS. 8A and 8B, the FD portions 21, the transfer gate electrodes 32, and the ground electrodes 33 are formed on the side on which the front surface S2 of the substrate 2 lies.

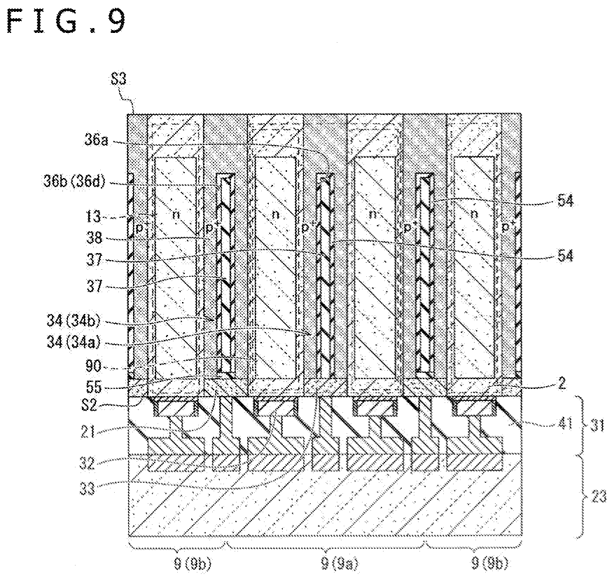

Next, as illustrated in FIG. 9, the wiring layer 31, having wires for reading electric charges and the transfer transistors, is formed, and the wiring layer 31 and the logic circuit board 23 are joined to each other. Next, a grinding process is performed on the rear surface S3 of the substrate 2, thereby reducing the thickness of the substrate 2 to a desired thickness. As a method for joining the wiring layer 31 and the logic circuit board 23 to each other, Cu—Cu junction of joining Cu pads to each other, and through terminals according to TSV (Through-Silicon Via) technology, for example, can be adopted.

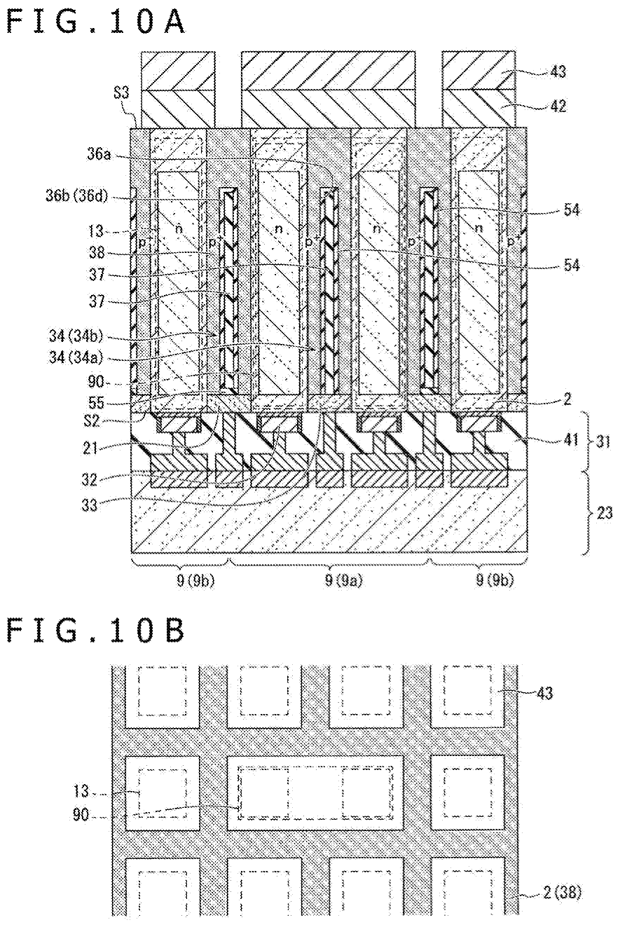

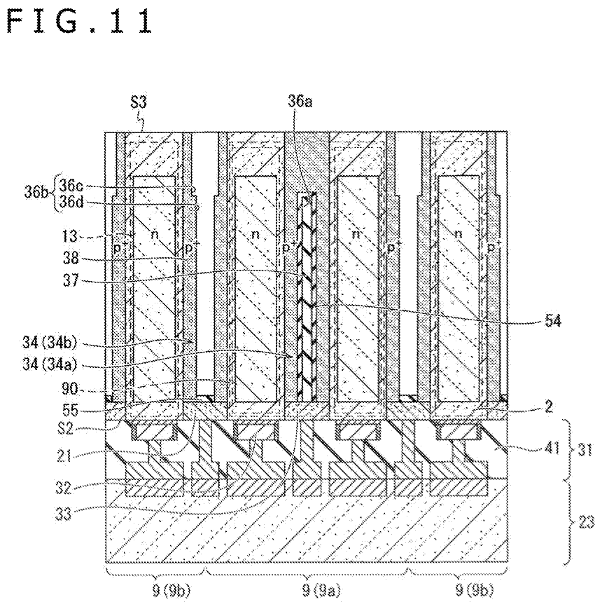

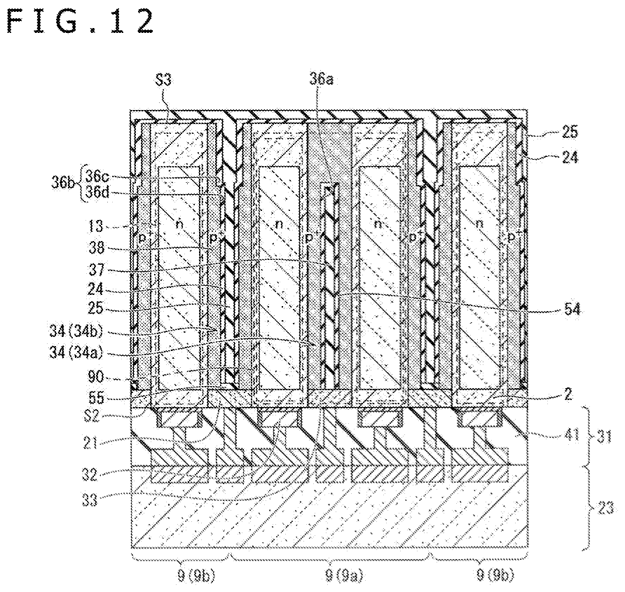

Next, as illustrated in FIGS. 10A and 10B, through a lithography technique and a dry etching technique, a hardmask using a hardmask material film 42 and a BARC film 43 is formed on the rear surface S3 of the substrate 2, and, as illustrated in FIG. 11, the first groove portions 36c are formed. Dry etching for the first groove portions 36c is performed such that each first groove portion 36c is formed over a region that overlaps with the second groove portion 36d in a plan view of a section of the substrate 2 parallel to the rear surface S3 so as to be deep enough to be joined to the second groove portion 36d in a side view of a section of the substrate 2 perpendicular to the rear surface S3. As a result, the second trench portions 36b are formed. Next, the filler 37 and the oxide film 54 are removed from the interior of each second groove portion 36d through a wet etching technique. This removal of the filler 37 and the oxide film 54 is performed up to a depth at which the stopper film 55 lies with the stopper film 55 functioning as an etching stopper. Next, as illustrated in FIG. 12, the pinning film 24 and the insulating film 25 are formed, in the order named, on the rear surface S3 of the substrate 2, the inside surfaces of the first groove portions 36c, and the inside surfaces of the second groove portion 36d. As a result, the second pixel separating portions 34b, each having the first groove portion 36c and the second groove portion 36d, having inside surfaces covered with the pinning film 24, and having the insulating film 25 (i.e., an oxide having a refractive index different from that of the substrate 2 (Si), for example, a highly refractive material) buried in the interior thereof, are formed.

Next, as illustrated in FIGS. 3A and 3B, the light-shielding film 26, the color filter layer 28, and the microlens layer 29 are formed, in the order named, on the rear surface S5 of the insulating film 25. As a result, the manufacture of the solid-state imaging device 1 having the phase difference pixels 9a and the normal pixels 9b according to the first embodiment is complete.

### 1-4 Example Modifications

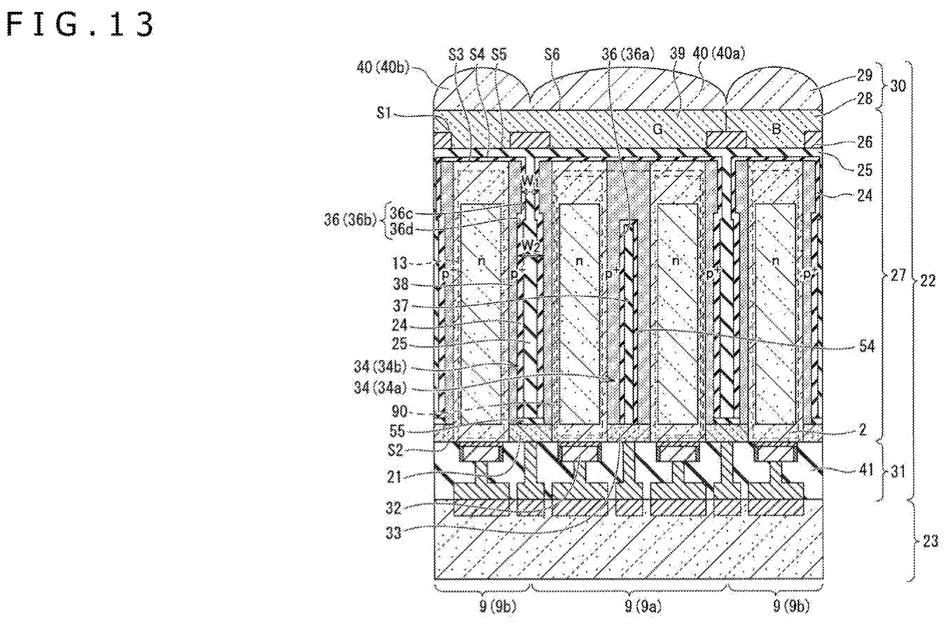

(1) Although, in the first embodiment described above by way of example, the width W₁ of the first groove portion 36c is greater than the width W₂ of the second groove portion 36d in the second trench portion 36b, another structure may alternatively be adopted. For example, as illustrated in FIG. 13, the width W₁ of the first groove portion 36c may alternatively be arranged to be smaller than the width W₂ of the second groove portion 36d in a section of the substrate 2 perpendicular to the rear surface S3.

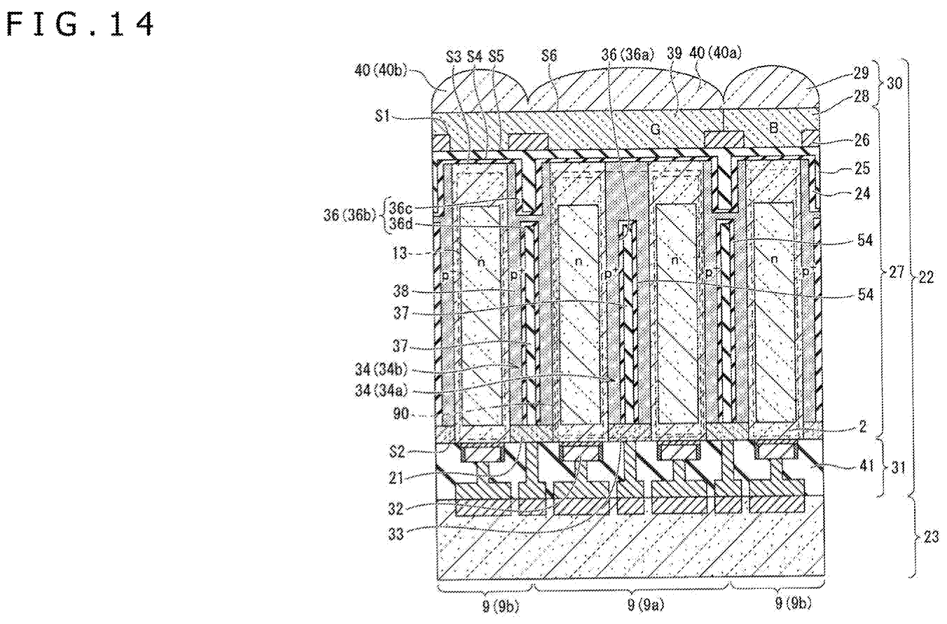

(2) Also, although the second groove portion 36d has a mouth portion at the bottom surface of the first groove portion 36c in the first embodiment described above by way of example, another structure may alternatively be adopted. For example, as illustrated in FIG. 14, the first groove portion 36c and the second groove portion 36d may alternatively be arranged to be apart from each other in the direction perpendicular to the rear surface S3 of the substrate 2. Note that no particular restrictions are placed on the distance by which the first groove portion 36c and the second groove portion 36d are arranged to be apart from each other. Also note that a material buried in the interior of the first groove portion 36c and a material buried in the interior of the second groove portion 36d may be either the same or different from each other. FIG. 14 illustrates an example case where the same filler 37 used for the first trench portion 36a is used as the material buried in the interior of the second groove portion 36d. In addition, in FIG. 14, the same oxide film 54 used for the first trench portion 36a is formed between the filler 37 and the inside surfaces of the second groove portion 36d. Arranging the first groove portion 36c and the second groove portion 36d to be apart from each other reduces required precision in the depth D₁ of the first groove portion 36c and the depth D₂ of the second groove portion 36d when compared to the case where the first groove portion 36c and the second groove portion 36d are arranged to be continuous with each other, and this can make the manufacture relatively easy.

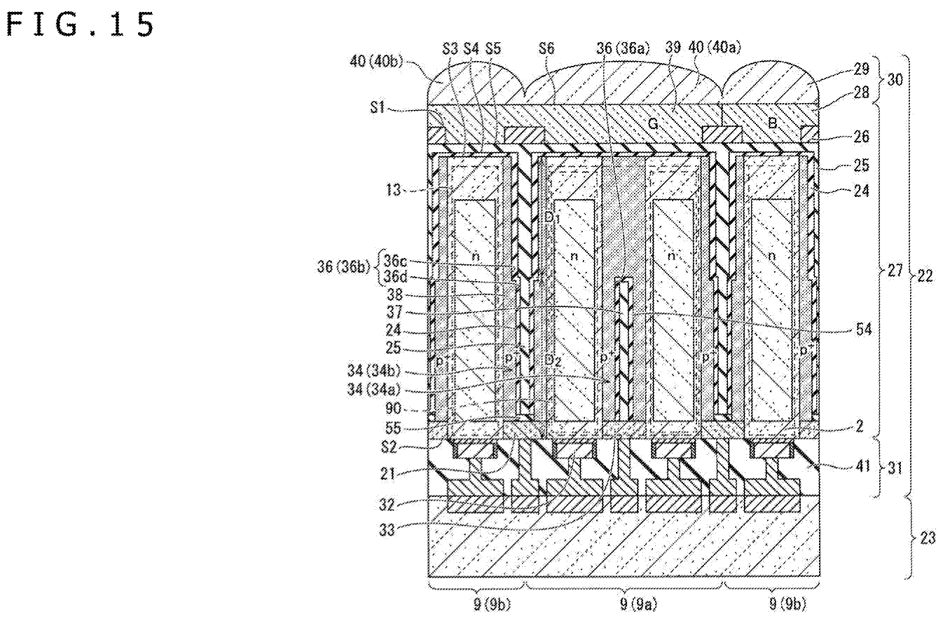

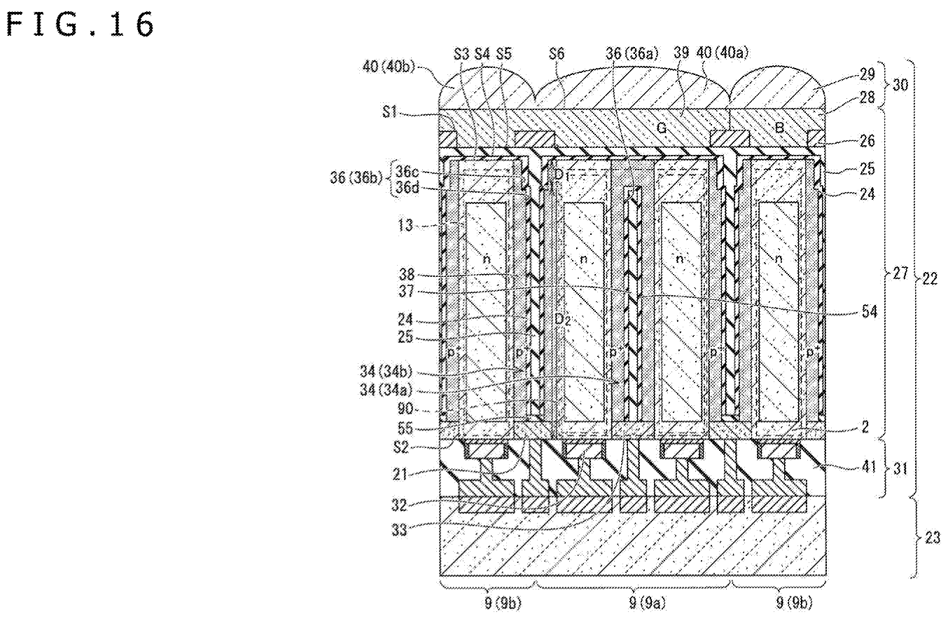

(3) Also, although the depth D₁ of the first groove portion 36c is smaller than the depth D₂ of the second groove portion 36d in the direction perpendicular to the rear surface S3 of the substrate 2 in the first embodiment described above by way of example, another structure may alternatively be adopted. For example, as illustrated in FIG. 15, the depth D₁ of the first groove portion 36c may be arranged to be greater than the depth D₁ of the first groove portion 36c illustrated in FIG. 3A, and as illustrated in FIG. 16, the depth D₁ of the first groove portion 36c may be arranged to be smaller than the depth D₁ of the first groove portion 36c illustrated in FIG. 3A. Here, in the case where green pixels (i.e., pixels provided with color filters 39 that allow green light to pass therethrough) are used as the phase difference pixels 9a, it is preferable that the depth D₁ of the first groove portion 36c be equal to or greater than 1 μm. Here, the depth D₁ of the first groove portion 36c is equal to the distance between the rear surface S3 of the substrate 2 and the end portion 35a of the first pixel separating portion 34a on the side closer to the rear surface S3. Because the distance between the rear surface S3 of the substrate 2 and the end portion 35a is thus equal to or greater than 1 μm, light passing through the color filter 39 is absorbed before reaching the depth of the end portion 35a, and is prevented from striking the first pixel separating portion 34a. Meanwhile, in the case where pixels that allow short-wavelength light to impinge thereon, such as blue pixels (i.e., pixels provided with color filters 39 that allow blue light to pass therethrough), are used as such, it is preferable that the depth D₁ of the first groove portion 36c be smaller than 1 μm. Meanwhile, in the case where pixels that allow long-wavelength light to impinge thereon, such as red pixels (i.e., pixels provided with color filters 39 that allow blue light to pass therethrough), are used as such, it is preferable that the depth D₁ of the first groove portion 36c be greater than 1 μm.

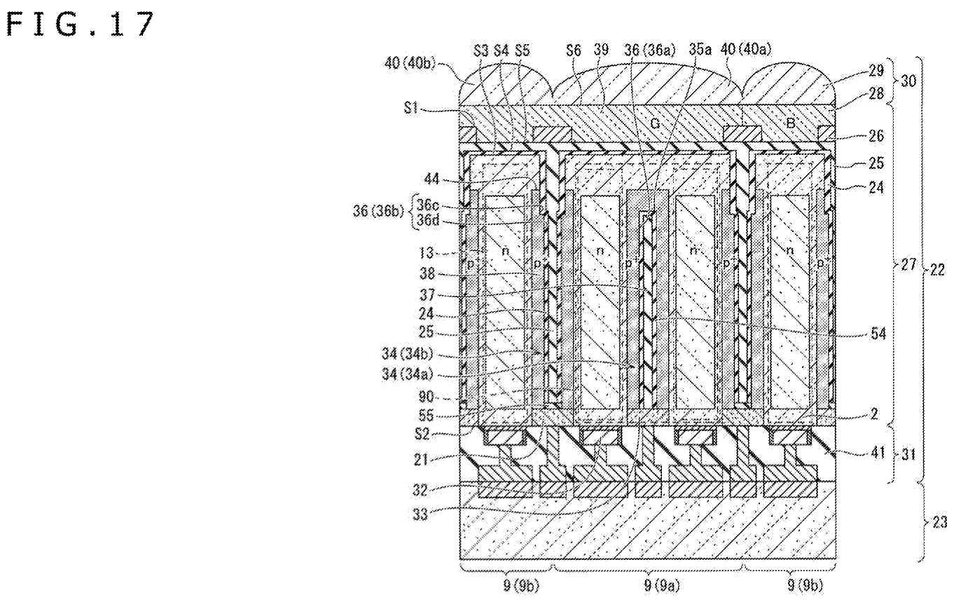

(4) Also, the size of the semiconductor region 38 of the opposite conductivity type and the method for forming the semiconductor region 38 of the opposite conductivity type are not limited to those illustrated in FIG. 3A and so on. For example, as illustrated in FIG. 17, an end portion 44 of the semiconductor region 38 of the opposite conductivity type on the side closer to the rear surface S3 may be positioned on the side of the rear surface S3 of the substrate 2 closer to the front surface S2. In this case, in the process of manufacturing the solid-state imaging device 1, a film including p-type impurities is formed on the inside surfaces of each of the second groove portions 36d and the first trench portions 36a, and the p-type impurities in the film are thereafter diffused through heat to accomplish sidewall diffusion, so that the semiconductor region 38 of the opposite conductivity type is formed. Note, however, that, to achieve a more favorable sensitivity ratio, the semiconductor region 38 of the opposite conductivity type is preferably formed so as to lie at a position on the side of the end portion 35a of the first pixel separating portion 34a closer to the rear surface S3 of the substrate 2. More preferably, the semiconductor region 38 of the opposite conductivity type is formed so as to adjoin the rear surface S3 of the substrate 2 as illustrated in FIG. 3A.

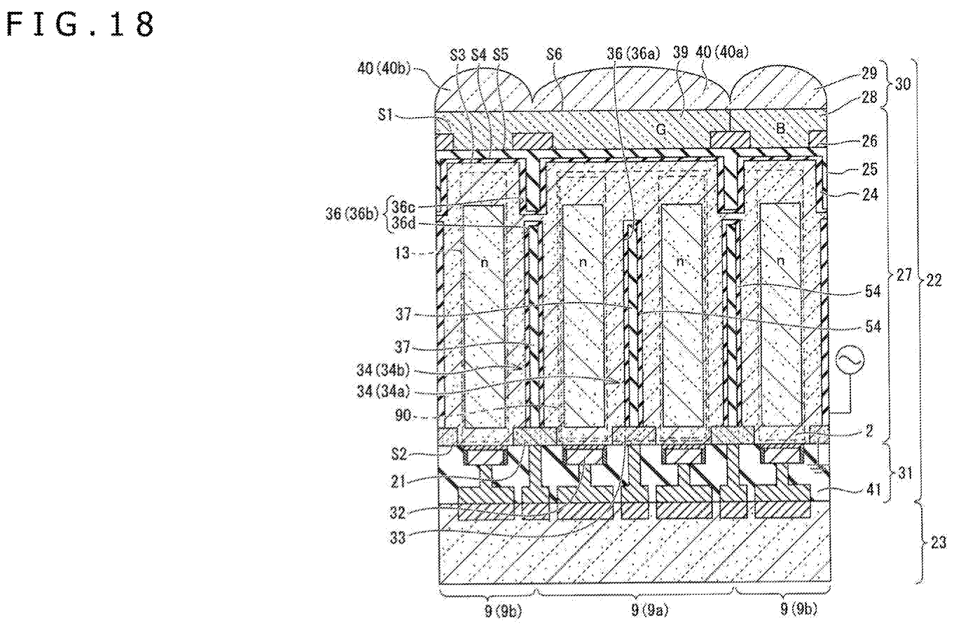

Also, as illustrated in FIG. 18, for example, in the case where a negative bias application operation of applying a negative bias to the filler 37 in the trench portion 36 to ensure pinning is to be performed, the semiconductor region 38 of the opposite conductivity type may be omitted. Note that FIG. 18 illustrates an example case where the semiconductor region 38 of the opposite conductivity type is omitted from the solid-state imaging device 1 according to the example modification illustrated in FIG. 14. In addition, examples of a method for supplying the negative bias include a method of supplying the negative bias through Cu—Cu junction, and a method of supplying the negative bias through the light-shielding film 26 (e.g., a grid of a light-shielding metal) on the rear surface S3 of the substrate 2 and a TSV. Also, in addition to the semiconductor region 38 of the opposite conductivity type between the photoelectric conversion part 13 and the pixel separating portions 34, a semiconductor region of the opposite conductivity type may additionally be formed on the side of the photoelectric conversion part 13 closer to the rear surface S3 of the substrate 2, for example.

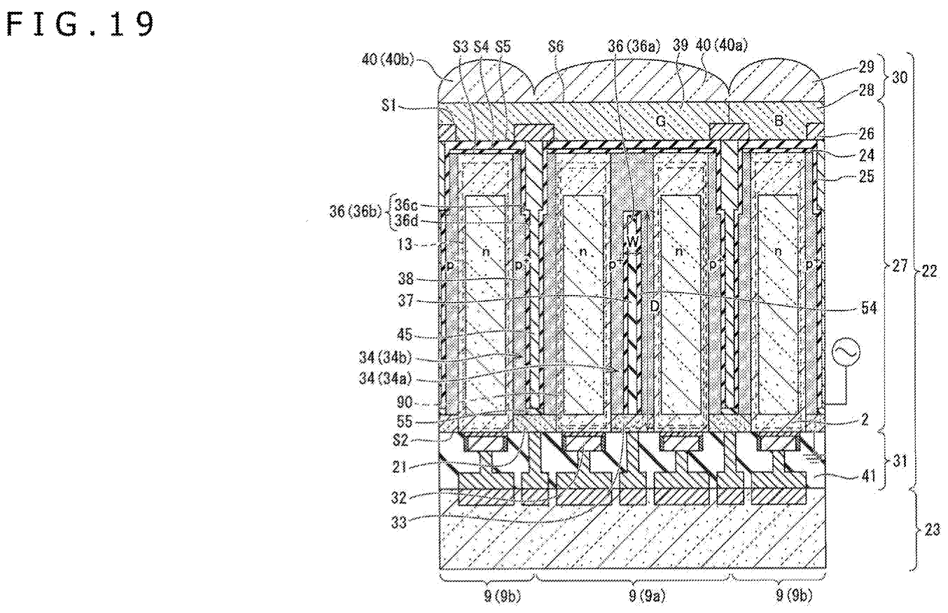

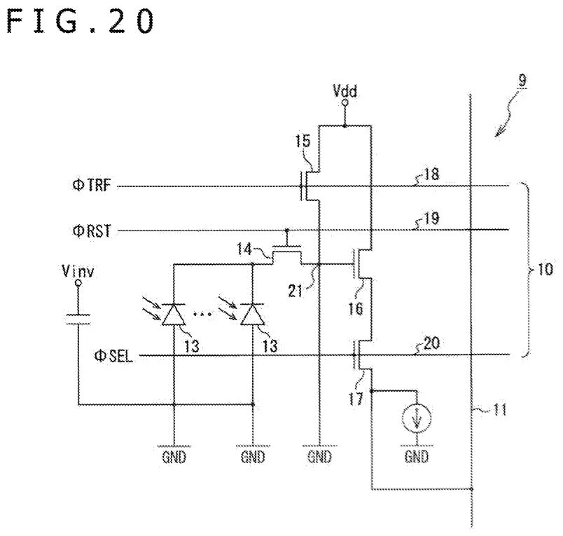

(5) Also, although the insulating film 25 is buried in the interior of the second trench portion 36b in the first embodiment described above by way of example, another structure may alternatively be adopted. For example, as illustrated in FIGS. 19 and 20, an electrically conductive material 45 may be buried in the interior of the second trench portion 36b, which may be applied to pixels 9 structured so as to allow the above-mentioned negative bias application operation to be performed thereon. FIG. 19 illustrates an example case where a voltage vinv illustrated in FIG. 20 is applied to the electrically conductive material 45 in the interior of the second trench portion 36b to form an inversion hole layer on side surfaces of the second pixel separating portion 34b. In addition, in FIG. 19, the pinning film 24 is arranged to cover only the rear surface S3 of the substrate 2. As the electrically conductive material 45, polysilicon (poly-Si), tungsten (W), or a transparent electrode, for example, can be adopted.

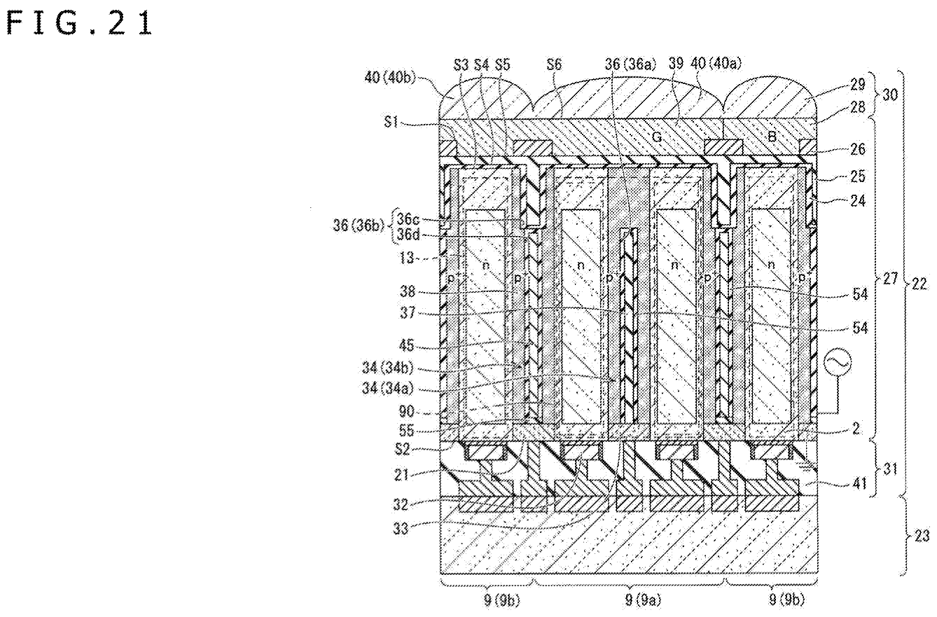

Also, as illustrated in FIG. 21, for example, the second trench portion 36b may be arranged to have a structure in which the inside surfaces and the bottom surface of the first groove portion 36c are covered with the pinning film 24 with the insulating film 25 or a gap buried in the interior thereof, while the electrically conductive material 45 is buried in the interior of the second groove portion 36d. FIG. 21 illustrates an example case where the insulating film 25 is buried in the interior of the first groove portion 36c. In addition, in FIG. 21, the same oxide film 54 used for the first trench portion 36a is formed between the electrically conductive material 45 and the inside surface of the second groove portion 36d. Arranging the pinning film 24 and the insulating film 25 (or the gap) in the first groove portion 36c, which does not involve absorption of light in contrast to the case where tungsten (W) or the like is arranged therein, contributes to improved efficiency in light utilization.

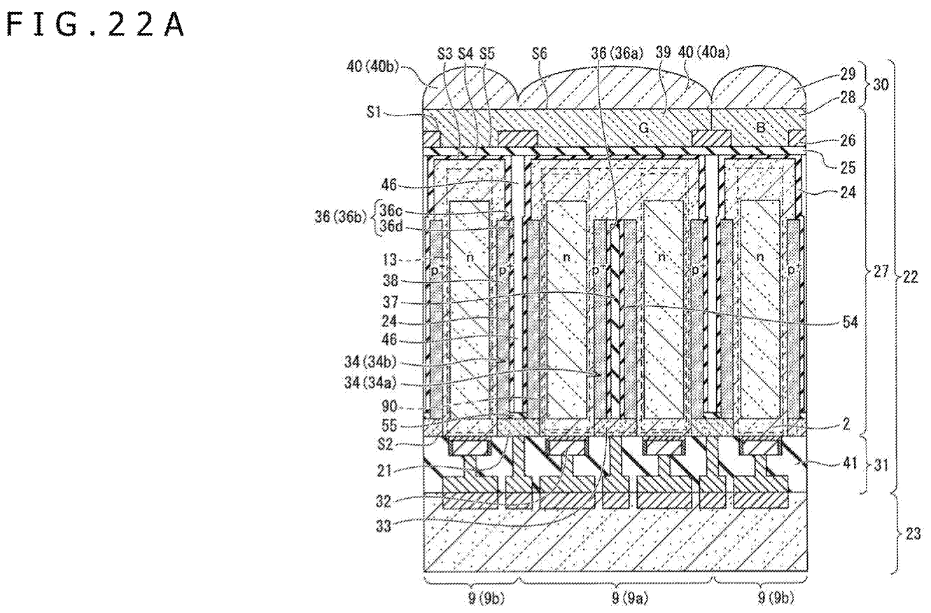

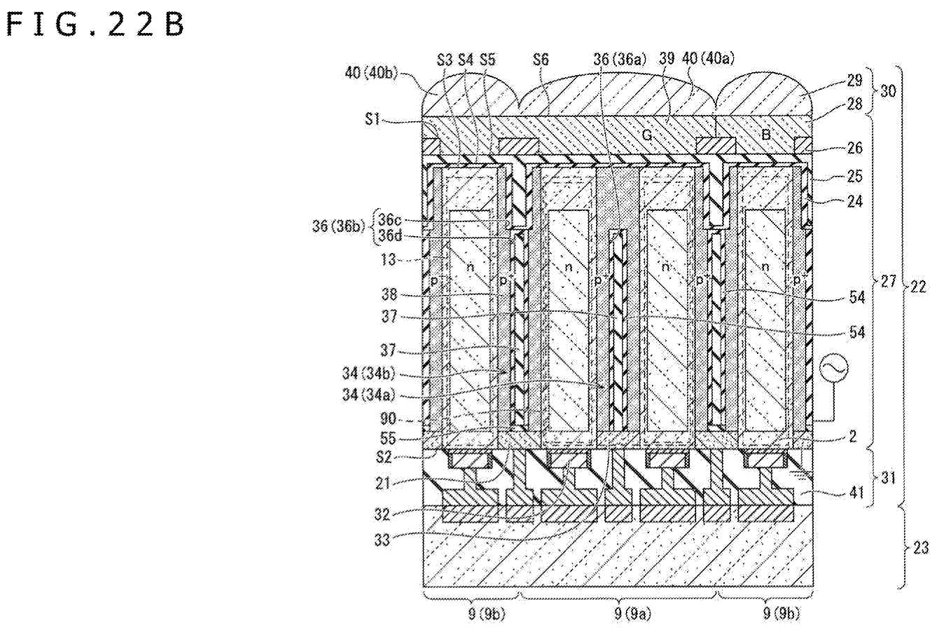

Also, as illustrated in FIG. 22A, for example, the interior of the second trench portion 36b may be formed by a gap 46. In this case, in the process of manufacturing the solid-state imaging device 1, after the filler 37 and so on are removed out of the second groove portion 36d together with the formation of the first groove portion 36c as illustrated in FIG. 11, only the pinning film 24 is formed on the inside surfaces of the first groove portion 36c and the inside surfaces of the second groove portion 36d as illustrated in FIG. 22A. The insulating film 25 is formed in the shape of a planar sheet parallel to the rear surface S3 of the substrate 2 so as to close the mouth portion of each first groove portion 36c, leaving the gap 46 in the interior of the first groove portion 36c. This leads to an increased difference in refractive index between the interior (i.e., air) of the second trench portion 36b and the substrate 2.

Also, as illustrated in FIG. 22B, for example, the structure in which the filler 37 is buried in the interior of the second trench portion 36b may be adopted. In this case, in the process of manufacturing the solid-state imaging device 1, neither the formation of the first groove portion 36c nor the removal of the filler 37 and so on out of the second groove portion 36d is performed.

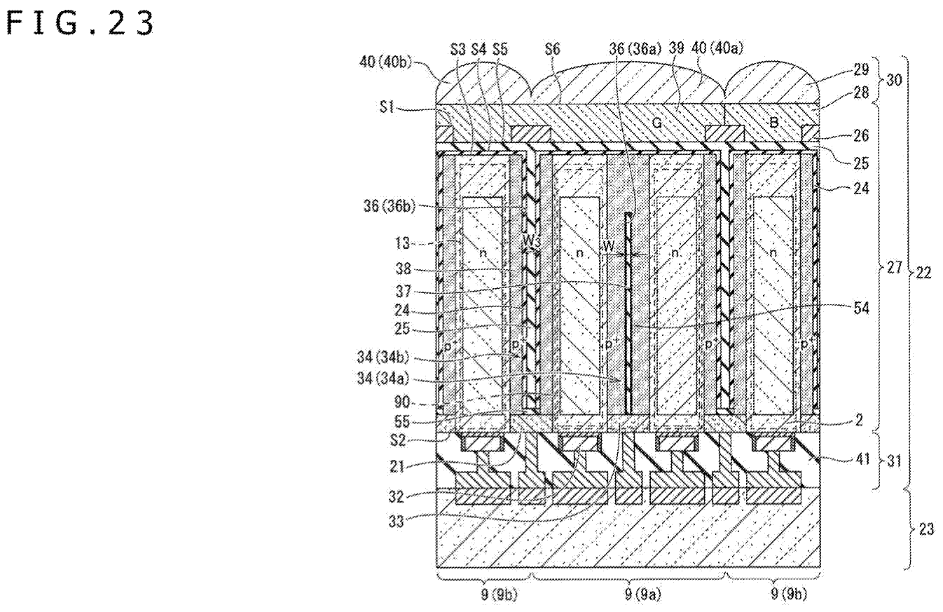

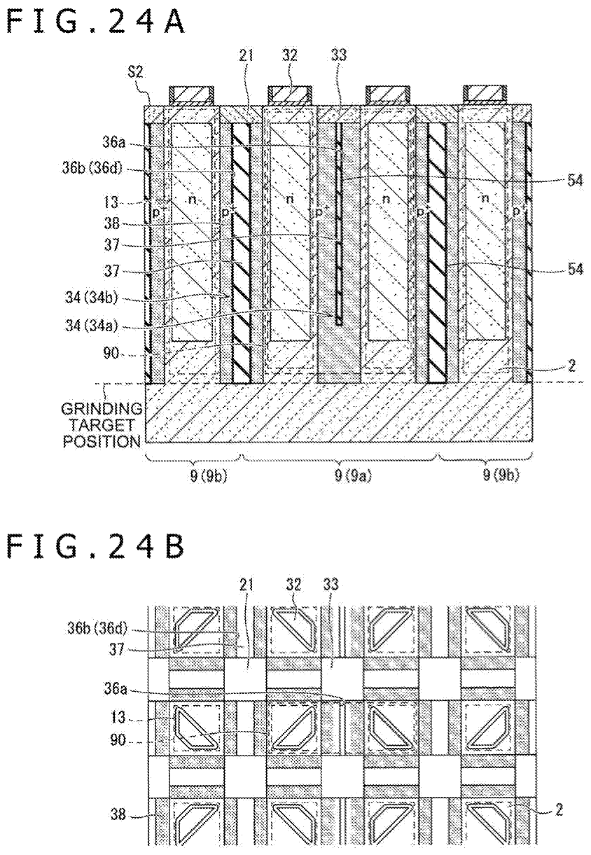

(6) Also, although the second trench portion 36b is formed by two groove portions (i.e., the first groove portion 36c and the second groove portion 36d) that have different groove widths W₁ and W₂ in the first embodiment described above by way of example, another structure may alternatively be adopted. For example, as illustrated in FIG. 23, the second trench portion 36b may alternatively be formed by a groove portion having a uniform groove width W₃. At this time, the groove width W of the first trench portion 36a may be arranged to be smaller than the groove width W₃ of the second trench portion 36b. In this case, in a mask that is used to form the first trench portions 36a and the second trench portions 36b in the process of manufacturing the solid-state imaging device 1, the width of opening portions corresponding to the first trench portions 36a is smaller than the width of opening portions corresponding to the second trench portions 36b. Thus, when dry etching is performed, the etching rate of the first trench portions 36a is slower than the etching rate of the second trench portions 36b due to a micro-loading effect, and as illustrated in FIGS. 24A and 24B, this enables simultaneous formation of the second trench portions 36b, which pass through the substrate 2, and the first trench portions 36a, which do not pass through the substrate 2. Note that, although FIG. 23 illustrates an example case where the insulating film 25 is buried in the interior of the second trench portion 36b, the structure in which the electrically conductive material 45 is buried therein as illustrated in FIG. 19, or the structure in which the gap 46 is formed therein as illustrated in FIG. 22, for example, may alternatively be adopted.

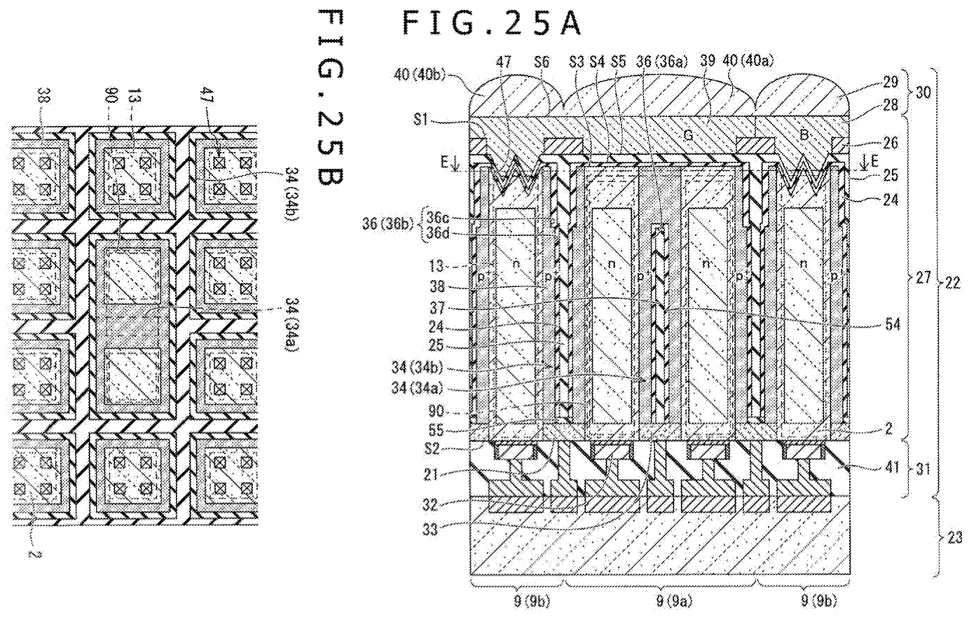

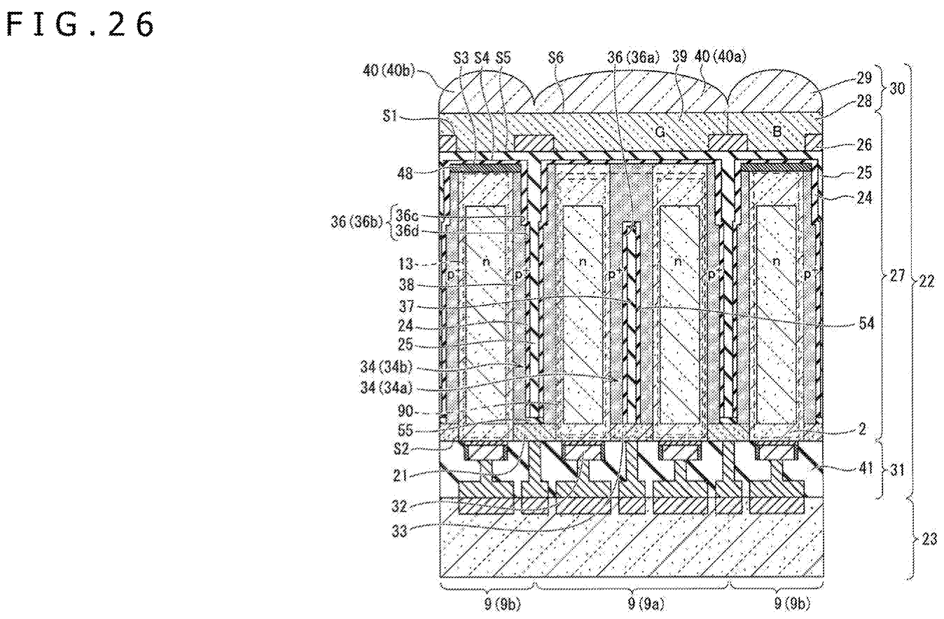

(7) Also, although the rear surface S3 of the substrate 2 is a flat surface in the first embodiment described above by way of example, another structure may alternatively be adopted. For example, as illustrated in FIGS. 25A and 25B, in each normal pixel 9b, multiple recessed portions 47 in the shape of an inverted pyramid may be formed at the rear surface S3 of the substrate 2, thus providing an antireflection portion having a moss eye structure. Also, as illustrated in FIG. 26, for example, in each normal pixel 9b, an antireflection film 48 may be provided at the rear surface S3 of the substrate 2. As the antireflection film 48, a single-layer film or a multilayer film, for example, can be adopted. The recessed portions 47 and the antireflection film 48 contribute to preventing reflection of incident light, leading to improved efficiency in light utilization. In addition, the structure in which the recessed portions 47 are provided contributes to increasing the amount of refraction of incident light, promoting reflection thereof between the second pixel separating portions 34b, and increasing the length of light paths.

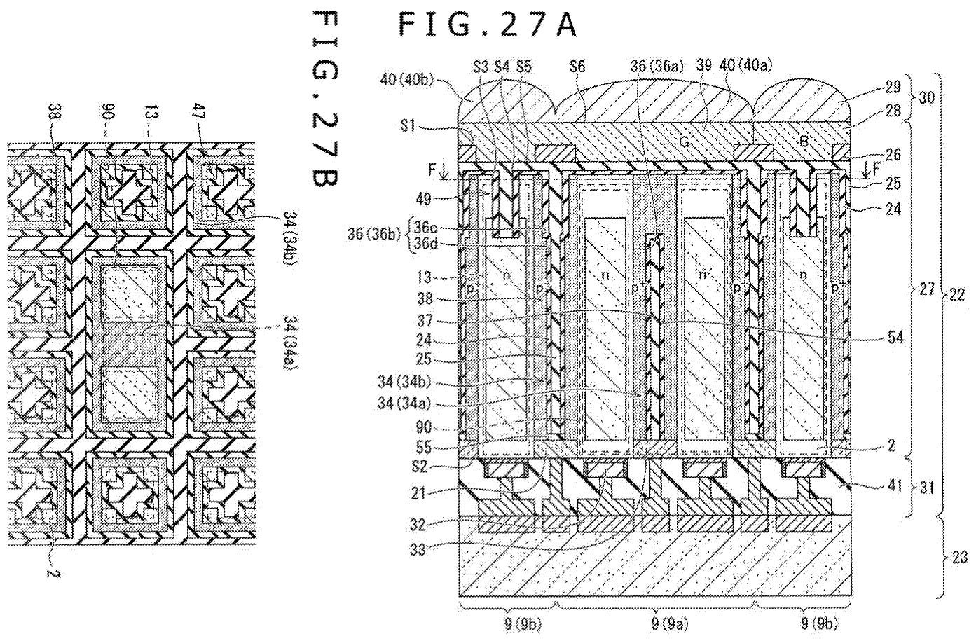

Also, as illustrated in FIGS. 27A and 27B, for example, in each normal pixel 9b, a scattering structure 49 for causing scattering of incident light may be formed at the rear surface S3 of the substrate 2. As the scattering structure 49, a structure having a groove portion having a cross-shaped mouth portion at the rear surface S3 of the substrate 2, a pinning film 24 covering the groove portion, and an insulating film 25 buried in an interior of the groove portion, for example, can be adopted.

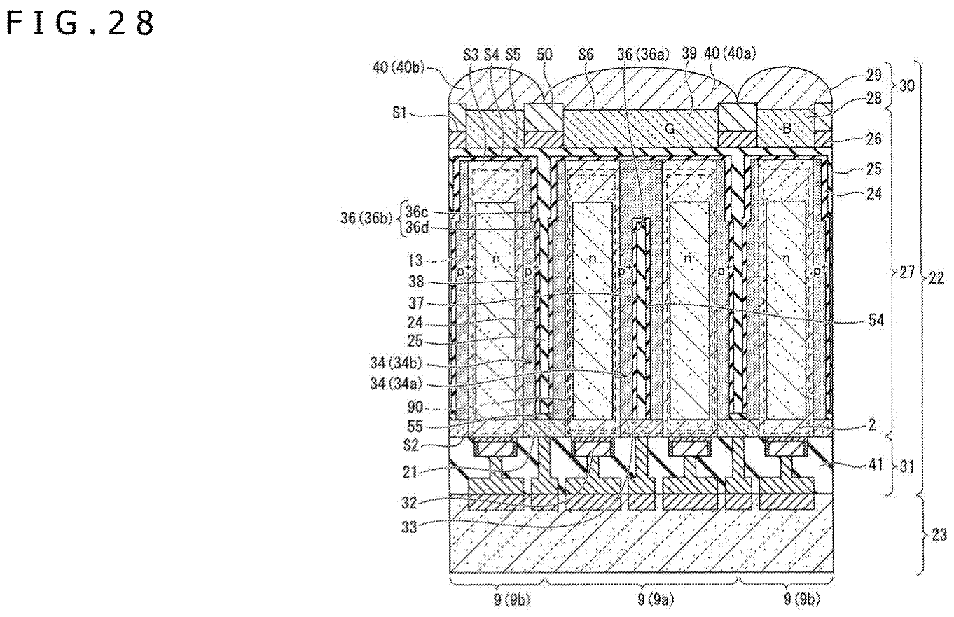

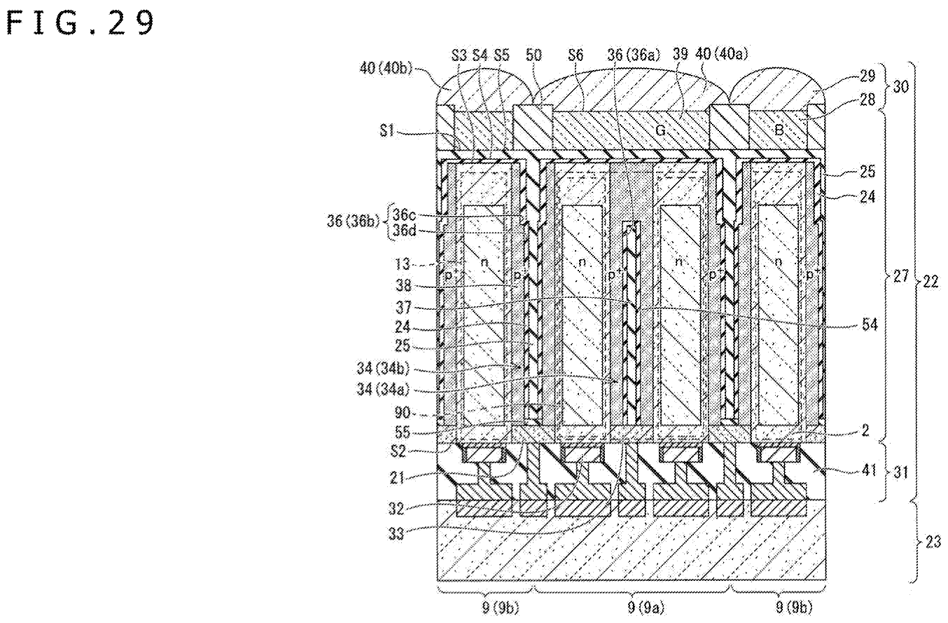

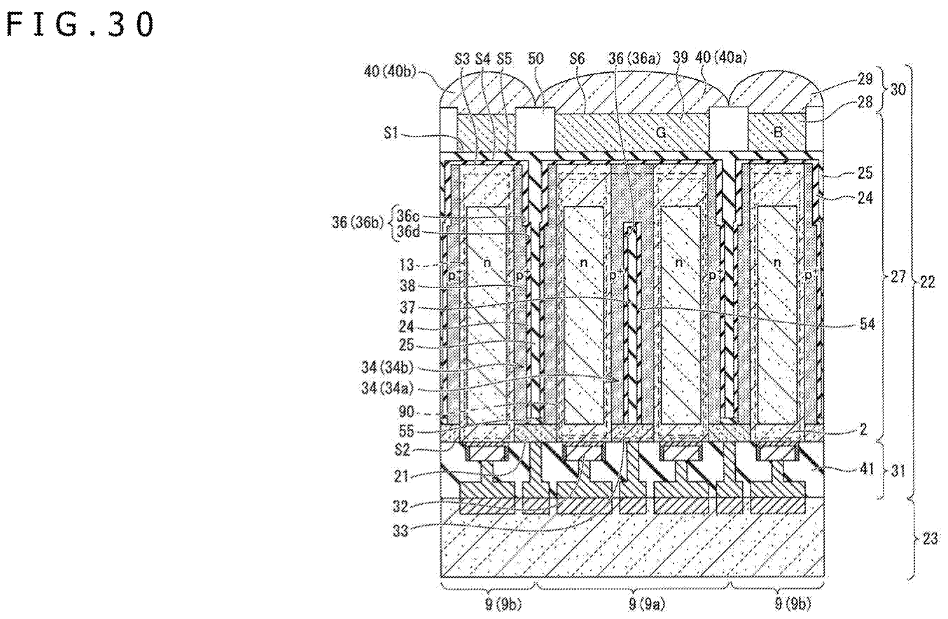

(8) Also, as illustrated in FIGS. 28, 29, and 30, for example, a color filter separating portion 50 may be arranged between the color filters 39. As the color filter separating portion 50, at least one of air, a metal, and a low refractive index material (e.g., a low refractive index resin) having a refractive index lower than that of the material of the color filters 39, for example, can be adopted. This will contribute to preventing light incident on a given color filter 39 from exiting therefrom to another color filter 39. FIG. 28 illustrates an example case where the color filter separating portion 50 includes a low refractive index material and is arranged between the color filters 39 and on the light-shielding film 26. Meanwhile, FIG. 29 illustrates an example case where the light-shielding film 26 is omitted, and the color filter separating portion 50 including a low refractive index material is formed also in places where the light-shielding film 26 lie in FIG. 28. Meanwhile, for example, FIG. 30 illustrates an example case where air (i.e., a gap) is used as the material of the color filter separating portion 50 illustrated in FIG. 29.

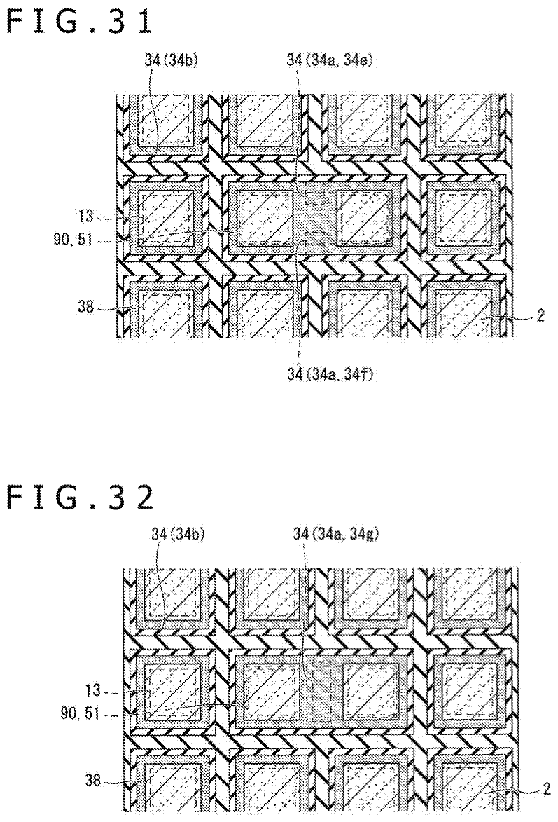

(9) Also, although, in the first embodiment described above by way of example, the pixel separating portions 34 are formed in a grid pattern when viewed from the side on which the microlens layer 29 lies as illustrated in FIG. 3C, another structure may alternatively be adopted. For example, as illustrated in FIG. 31, each first pixel separating portion 34a may be formed by two pixel separating portions 34e and 34f that project into a set 51 of two photoelectric conversion parts 13 adjacent to the first pixel separating portion 34a from two sides in an outer periphery of the set 51, the two sides lying opposite to each other in a direction perpendicular to the direction in which the two photoelectric conversion parts 13 are arranged, when viewed from the side on which the microlens layer 29 lies. That is, a structure in which a middle portion of the first pixel separating portion 34a illustrated in FIG. 3C when viewed from the side on which the microlens layer 29 lies is omitted may be adopted. Also, as illustrated in FIG. 32, for example, each first pixel separating portion 34a may be formed by a pixel separating portion 34g isolated from the other pixel separating portions 34, with both end portions of the first pixel separating portion 34a illustrated in FIG. 3C being omitted, when viewed from the side on which the microlens layer 29 lies. Each of FIGS. 31 and 32 is a diagram illustrating the structure of a section of the solid-state imaging device 1 taken along a position corresponding to line B-B in FIG. 3A.

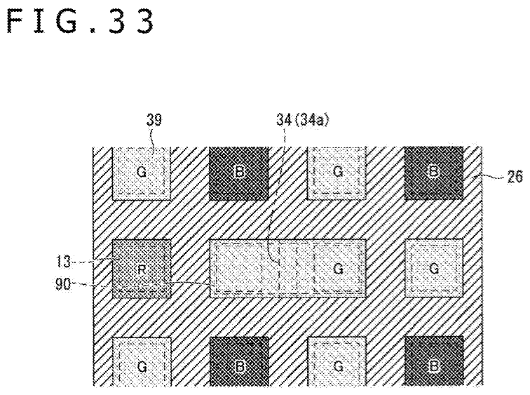

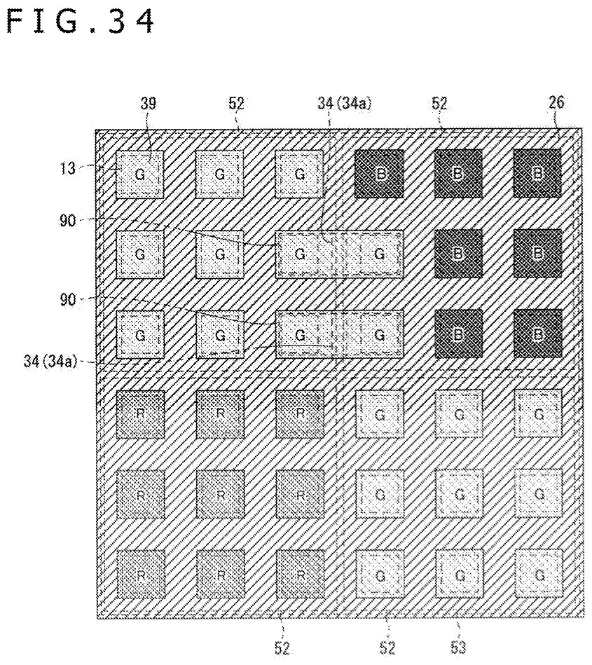

(10) Also, although the array pattern of the color filters 39 in the first embodiment described above by way of example is a Quad-Bayer array modified such that at least one of the color filters 39 therein is substituted with another color filter 39, another structure may alternatively be adopted. For example, as illustrated in FIG. 33, the array pattern of the color filters 39 may be a Bayer array modified such that at least one of color filters in the Bayer array is substituted with another color filter to arrange color filters 39 of the same color (e.g., R filters that allow red light to pass therethrough, G filters that allow green light to pass therethrough, or B filters that allow blue light to pass therethrough) for the photoelectric conversion parts 13 in the same photoelectric conversion part group 90. Also, as illustrated in FIGS. 34, 35, 36, 37, 38, and 39, for example, the array pattern of the color filters 39 may be a modified 2m×2m array in which color filter unit groups 53 are cyclically arranged, each color filter unit group 53 including a 2×2 array of color filter units 52 each including m×m (m is a natural number equal to or greater than 2) color filters 39 of the same color, the 2m×2m array being modified such that at least one of the color filters 39 in the 2m×2m array is substituted with another color filter 39. FIGS. 34 to 39 each illustrate an example case where m=3, while FIG. 3B illustrates an example case where m=2. Each of FIGS. 33 to 39 is a diagram illustrating the structure of a section of the solid-state imaging device 1 taken along a position corresponding to line C-C in FIG. 3A.

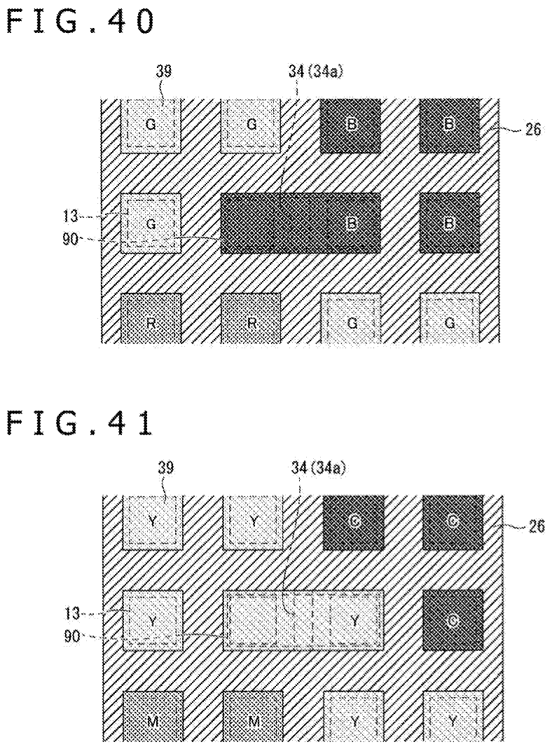

(11) Also, although, in the first embodiment described above by way of example, G filters, which allow green light to pass therethrough, are used as the color filters 39 for the phase difference pixels 9a, another structure may alternatively be adopted. For example, as illustrated in FIG. 40, RGB color filters of another color, such as B filters, which allow blue light to pass therethrough, or R filters, which allow red light to pass therethrough, may alternatively be used as such. FIG. 40 illustrates an example case where B filters are alternatively used as such. Also, as illustrated in FIG. 41, for example, in the case where complementary color filters, such as C filters, which allow cyan light to pass therethrough, M filters, which allow magenta light to pass therethrough, and Y filters, which allow yellow light to pass therethrough, are used as the color filters 39, complementary color filters of any of the colors may be used as such. FIG. 41 illustrates an example case where Y filters are used as the color filters 39 for the phase difference pixels 9a. Also, as illustrated in FIG. 42, for example, color filters such as ND filters, transparent color filters, or gray filters may alternatively be used as such. FIG. 42 illustrates an example case where ND filters are used as such. Also, for example, a structure in which the color filters 39 for the phase difference pixels 9a are omitted may be adopted.

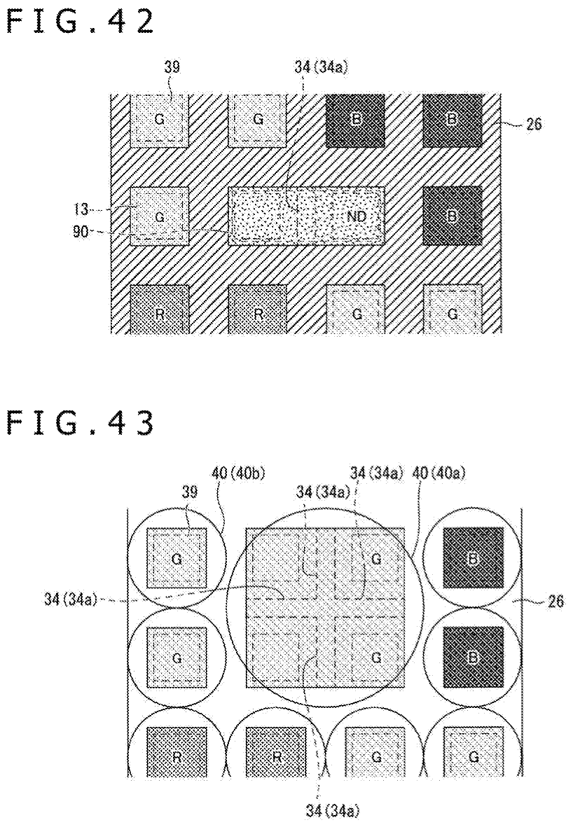

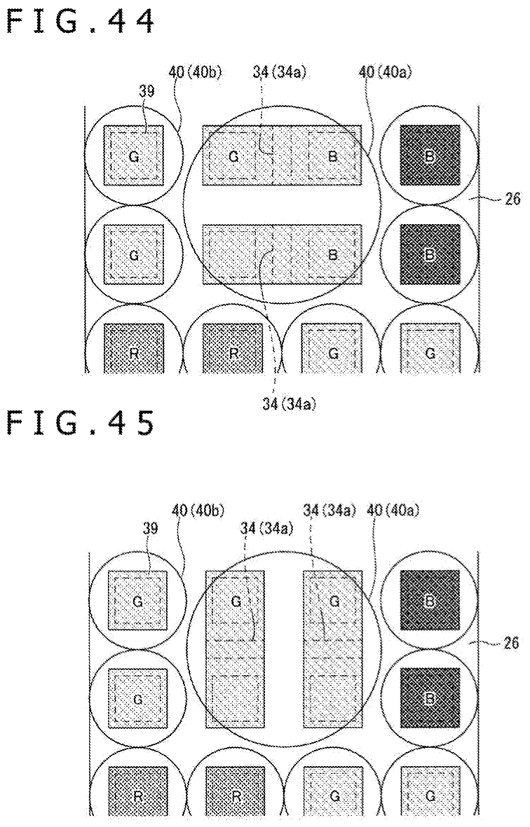

(12) Also, although in the first embodiment described above by way of example, with respect to the phase difference pixels 9a, one microlens 40 is arranged for each photoelectric conversion part group 90 including 2×1, i.e., two, photoelectric conversion parts 13, another structure may alternatively be adopted. For example, as illustrated in FIGS. 43, 44, and 45, one microlens 40 may be arranged for each of photoelectric conversion part groups 90 each including n×n (n is a natural number equal to or greater than 2), i.e., n², photoelectric conversion parts 13. Each of FIGS. 43 to 45 illustrates an example case where n=2. In addition, FIG. 43 illustrates an example case where the first pixel separating portions 34a are arranged between all of the photoelectric conversion parts 13 in each photoelectric conversion part group 90. The first pixel separating portions 34a illustrated in FIG. 43 are arranged in the shape of a cross when viewed from the side on which the microlens layer 29 lies. Meanwhile, each of FIGS. 44 and 45 illustrates an example case where the first pixel separating portions 34a are arranged in two of four regions between adjacent ones of the photoelectric conversion parts 13 in the photoelectric conversion part group 90, while the second pixel separating portion 34b is arranged in the remaining ones of the regions between adjacent ones of the photoelectric conversion parts 13. The first pixel separating portions 34a illustrated in FIG. 44 are arranged only in a column direction (i.e., the vertical direction in FIG. 44). Meanwhile, the first pixel separating portions 34a illustrated in FIG. 45 are arranged only in a row direction (i.e., the left-right direction in FIG. 45).

(13) In addition, the present technology is applicable not only to a solid-state imaging device as an image sensor as described above, but also to photodetection devices in general, including, for example, a distance measuring sensor for distance measurement, also called a ToF (Time of Flight) sensor. The distance measuring sensor is a sensor that emits irradiation light toward an object, detects returning reflected light resulting from the irradiation light being reflected by a surface of the object, and calculates the distance to the object on the basis of the time of flight from the emission of the irradiation light to reception of the reflected light. As the structure of light receiving pixels of this distance measuring sensor, the above-described structures of the pixels 9 can be adopted.

### 2. Second Embodiment: Example of Application to Electronic Device

The technology according to the present disclosure (i.e., the present technology) may be applied to various types of electronic devices.

FIG. 46 is a diagram illustrating an example schematic structure of an imaging device (e.g., a video camera, a digital still camera, etc.) as an electronic device to which the present disclosure is applied.

As illustrated in FIG. 46, the imaging device 1000 includes a lens group 1001, a solid-state imaging device 1002 (i.e., the solid-state imaging device 1 according to the first embodiment), a DSP (Digital Signal Processor) circuit 1003, a frame memory 1004, a monitor 1005, and a memory 1006. The DSP circuit 1003, the frame memory 1004, the monitor 1005, and the memory 1006 are connected to one another via a bus line 1007.

The lens group 1001 guides incident light (i.e., image-forming light) from a subject to the solid-state imaging device 1002 to form an image on a light receiving surface (i.e., a pixel region) of the solid-state imaging device 1002.

The solid-state imaging device 1002 is formed by the CMOS image sensor according to the first embodiment described above. The solid-state imaging device 1002 converts the amounts of incident light guided by the lens group 1001 to form an image on the light receiving surface to electrical signals on a pixel-by-pixel basis, and supplies the electrical signals to the DSP circuit 1003 as pixel signals.

The DSP circuit 1003 performs predetermined image processing on the pixel signals supplied from the solid-state imaging device 1002. Then, the DSP circuit 1003 supplies image signals obtained after the image processing to the frame memory 1004 on a frame-by-frame basis to cause the image signals to be temporarily stored in the frame memory 1004.

The monitor 1005 is formed by, for example, a panel-type display device, such as a liquid crystal panel or an organic EL (Electro Luminescence) panel. The monitor 1005 displays images (video) of the subject on the basis of the frame-by-frame pixel signals temporarily stored in the frame memory 1004.

The memory 1006 is formed by a DVD, a flash memory, or the like. The memory 1006 reads and records the frame-by-frame pixel signals temporarily stored in the frame memory 1004.

Note that electronic devices to which the solid-state imaging device 1 is applicable are not limited to the imaging device 1000, and that the solid-state imaging device 1 is applicable to other electronic devices as well.

Also note that, although it has been assumed that the solid-state imaging device 1 according to the first embodiment is used as the solid-state imaging device 1002, another structure may alternatively be adopted. For example, another photodetection device to which the present technology has been applied, such as the solid-state imaging device 1 according to an example modification of the first embodiment, may be used as such.

Note that the present technology may be implemented in the following configurations.

(1)

A photodetection device including:
a substrate;
multiple pixels arranged two-dimensionally in the substrate, and including photoelectric conversion parts;
a microlens layer arranged on a side of the substrate on which a light receiving surface of the substrate lies, and including multiple microlenses for concentrating incident light onto the photoelectric conversion parts; and
pixel separating portions arranged between the photoelectric conversion parts in the substrate, and having trench portions, in which
the multiple pixels include normal pixels and phase difference pixels,
the multiple microlenses include individual-type microlenses each formed for a separate one of the photoelectric conversion parts included in the normal pixels, and shared-type microlenses each formed for a separate one of photoelectric conversion part groups each including the photoelectric conversion parts included in adjacent ones of the phase difference pixels, and
the pixel separating portions include first pixel separating portions arranged between at least some of the photoelectric conversion parts in each photoelectric conversion part group, and second pixel separating portions arranged between the photoelectric conversion parts where none of the first pixel separating portions is arranged, and an end portion of each first pixel separating portion on a side closer to the light receiving surface is positioned on a side of the light receiving surface of the substrate closer to a surface of the substrate opposite to the light receiving surface, while an end portion of each second pixel separating portion on the side closer to the light receiving surface is positioned closer to the light receiving surface than is the end portion of the first pixel separating portion on the side closer to the light receiving surface.
   (2)

The photodetection device according to (1) above, in which
the first pixel separating portions are arranged between every adjacent ones of the photoelectric conversion parts in each photoelectric conversion part group, and
the second pixel separating portions are arranged between the photoelectric conversion parts included in adjacent ones of the normal pixels and between some of the photoelectric conversion parts included in the normal pixels and some of the photoelectric conversion parts in the photoelectric conversion part groups that are adjacent to the some photoelectric conversion parts.
   (3)

The photodetection device according to (1) or (2) above, in which the trench portion of each second pixel separating portion is formed by two groove portions having different groove widths.

(4)

The photodetection device according to (3) above, in which the two groove portions are a first groove portion having a mouth portion at the light receiving surface of the substrate, and extending in a direction perpendicular to the light receiving surface of the substrate, and a second groove portion having mouth portions at a bottom surface of the first groove portion and at the surface of the substrate opposite to the light receiving surface, and extending in the direction perpendicular to the light receiving surface of the substrate.

(5)

The photodetection device according to (3) above, in which the two groove portions are a first groove portion having a mouth portion at the light receiving surface of the substrate, and extending in a direction perpendicular to the light receiving surface of the substrate, and a second groove portion being apart from the first groove portion in the direction perpendicular to the light receiving surface of the substrate, having a mouth portion at the surface of the substrate opposite to the light receiving surface, and extending in the direction perpendicular to the light receiving surface of the substrate.

(6)

The photodetection device according to (1) or (2) above, in which
the trench portion of each second pixel separating portion is a groove portion having a uniform groove width, and
the trench portion of each first pixel separating portion has a groove width smaller than the groove width of the trench portion of the second pixel separating portion.
   (7)

The photodetection device according to any one of (1) to (6) above, in which the substrate has a semiconductor region of a conductivity type opposite to that of a charge accumulation region of each photoelectric conversion part, the semiconductor region being formed between the photoelectric conversion part and the trench portions.

(8)

The photodetection device according to any one of (1) to (7) above, including:
a color filter layer arranged between the substrate and the microlens layer, and including multiple color filters that allow light of specific wavelengths included in light collected and condensed by the microlenses to pass therethrough; and
a color filter separating portion arranged between the color filters, in which
the color filter separating portion is formed by at least one of air, a metal, and a low refractive index material having a refractive index lower than that of a material of the color filters.
   (9)

The photodetection device according to any one of (1) to (8) above, in which each normal pixel has multiple recessed portions in a shape of an inverted pyramid at the light receiving surface of the substrate.

(10)

The photodetection device according to any one of (1) to (9) above, including:
a color filter layer arranged between the substrate and the microlens layer, and including multiple color filters that allow light of specific wavelengths included in the light collected and condensed by the microlenses to pass therethrough, in which
an array pattern of the color filters is a Bayer array modified such that at least one of color filters in the Bayer array is substituted with another color filter to arrange color filters of the same color for the photoelectric conversion parts in the same photoelectric conversion part group, or a modified 2m×2m array in which color filter unit groups are cyclically arranged, each color filter unit group including a 2×2 array of color filter units each including m×m (m is a natural number equal to or greater than 2) color filters of the same color, the 2m×2m array being modified such that at least one of the color filters in the 2m×2m array is substituted with another color filter.
   (11)

The photodetection device according to any one of (1) to (10) above, in which each photoelectric conversion part group includes 2×1, i.e., two, of the photoelectric conversion parts, or n×n (n is a natural number equal to or greater than 2), i.e., n², of the photoelectric conversion parts.

(12)

The photodetection device according to any one of (1) to (11) above, in which each first pixel separating portion is formed by two of the pixel separating portions that project into a set of two of the photoelectric conversion parts adjacent to the first pixel separating portion from each of two sides in an outer periphery of the set, the two sides lying opposite to each other in a direction perpendicular to a direction in which the two photoelectric conversion parts are arranged, when viewed from a side on which the microlens layer lies.

(13)

An electronic device including:
a photodetection device including
   a substrate,
   multiple pixels arranged two-dimensionally in the substrate, and including photoelectric conversion parts,
   a microlens layer arranged on a side of the substrate on which a light receiving surface of the substrate lies, and including multiple microlenses for concentrating incident light onto the photoelectric conversion parts, and
   pixel separating portions arranged between the photoelectric conversion parts in the substrate, and having trench portions, in which
the multiple pixels include normal pixels and phase difference pixels,
the multiple microlenses include individual-type microlenses each formed for a separate one of the photoelectric conversion parts included in the normal pixels, and shared-type microlenses each formed for a separate one of photoelectric conversion part groups each including the photoelectric conversion parts included in adjacent ones of the phase difference pixels, and
the pixel separating portions include first pixel separating portions arranged between at least some of the photoelectric conversion parts in each photoelectric conversion part group, and second pixel separating portions arranged between the photoelectric conversion parts where none of the first pixel separating portions is arranged, and an end portion of each first pixel separating portion on a side closer to the light receiving surface is positioned on a side of the light receiving surface of the substrate closer to a surface of the substrate opposite to the light receiving surface, while an end portion of each second pixel separating portion on the side closer to the light receiving surface is positioned closer to the light receiving surface than is the end portion of the first pixel separating portion on the side closer to the light receiving surface.

### REFERENCE SIGNS LIST

1: Solid-state imaging device
2: Substrate
3: Pixel region
4: Vertical drive circuit
5: Column signal processing circuit
6: Horizontal drive circuit
7: Output circuit
8: Control circuit
9: Pixel
9a: Phase difference pixel
9b: Normal pixel
10: Pixel drive wire
11: Vertical signal line
12: Horizontal signal line
13: Photoelectric conversion part
14: Transfer transistor
15: Reset transistor
16: Amplification transistor
17: Selection transistor
18: Transfer line
19: Reset line
20: Selection line
21: FD portion
22: Image sensor board
23: Logic circuit board
24: Pinning film
25: Insulating film
26: Light-shielding film
27: Light reception layer
28: Color filter layer
29: Microlens layer
30: Light condensation layer
31: Wiring layer
32: Transfer gate electrode
33: Ground electrode
34, 34e, 34f, 34g: Pixel separating portion
34a: First pixel separating portion
34b: Second pixel separating portion
35a: End portion
35b: End portion
36: Trench portion
36a: First trench portion
36b: Second trench portion
36c: First groove portion
36d: Second groove portion
37: Filler
38: Semiconductor region
39: Color filter
40: Microlens
40a: Shared-type microlens
40b: Individual microlens
41: Interlayer insulating film
42: Hardmask material film
43: BARC film
44: End portion
45: Electrically conductive material
46: Gap
47: Recessed portion
48: Antireflection film
49: Scattering structure
50: Color filter separating portion
51: Set
52: Color filter unit
53: Color filter unit group
54: Oxide film
55: Stopper film
90: Photoelectric conversion part group

1. A photodetection device comprising:
a substrate;
multiple pixels arranged two-dimensionally in the substrate, and including photoelectric conversion parts;
a microlens layer arranged on a side of the substrate on which a light receiving surface of the substrate lies, and including multiple microlenses for concentrating incident light onto the photoelectric conversion parts; and
pixel separating portions arranged between the photoelectric conversion parts in the substrate, and having trench portions, wherein
the multiple pixels include normal pixels and phase difference pixels,
the multiple microlenses include individual-type microlenses each formed for a separate one of the photoelectric conversion parts included in the normal pixels, and shared-type microlenses each formed for a separate one of photoelectric conversion part groups each including the photoelectric conversion parts included in adjacent ones of the phase difference pixels, and
the pixel separating portions include first pixel separating portions arranged between at least some of the photoelectric conversion parts in each photoelectric conversion part group, and second pixel separating portions arranged between the photoelectric conversion parts where none of the first pixel separating portions is arranged, and an end portion of each first pixel separating portion on a side closer to the light receiving surface is positioned on a side of the light receiving surface of the substrate closer to a surface of the substrate opposite to the light receiving surface, while an end portion of each second pixel separating portion on the side closer to the light receiving surface is positioned closer to the light receiving surface than is the end portion of the first pixel separating portion on the side closer to the light receiving surface.

2. The photodetection device according to claim 1, wherein
the first pixel separating portions are arranged between every adjacent ones of the photoelectric conversion parts in each photoelectric conversion part group, and
the second pixel separating portions are arranged between the photoelectric conversion parts included in adjacent ones of the normal pixels and between some of the photoelectric conversion parts included in the normal pixels and some of the photoelectric conversion parts in the photoelectric conversion part groups that are adjacent to the some photoelectric conversion parts.

3. The photodetection device according to claim 1, wherein the trench portion of each second pixel separating portion is formed by two groove portions having different groove widths.

4. The photodetection device according to claim 3, wherein the two groove portions are a first groove portion having a mouth portion at the light receiving surface of the substrate, and extending in a direction perpendicular to the light receiving surface of the substrate, and a second groove portion having mouth portions at a bottom surface of the first groove portion and at the surface of the substrate opposite to the light receiving surface, and extending in the direction perpendicular to the light receiving surface of the substrate.

5. The photodetection device according to claim 3, wherein the two groove portions are a first groove portion having a mouth portion at the light receiving surface of the substrate, and extending in a direction perpendicular to the light receiving surface of the substrate, and a second groove portion being apart from the first groove portion in the direction perpendicular to the light receiving surface of the substrate, having a mouth portion at the surface of the substrate opposite to the light receiving surface, and extending in the direction perpendicular to the light receiving surface of the substrate.

6. The photodetection device according to claim 1, wherein
the trench portion of each second pixel separating portion is a groove portion having a uniform groove width, and
the trench portion of each first pixel separating portion has a groove width smaller than the groove width of the trench portion of the second pixel separating portion.

7. The photodetection device according to claim 1, wherein the substrate has a semiconductor region of a conductivity type opposite to that of a charge accumulation region of each photoelectric conversion part, the semiconductor region being formed between the photoelectric conversion part and the trench portions.

8. The photodetection device according to claim 1, comprising:
a color filter layer arranged between the substrate and the microlens layer, and including multiple color filters that allow light of specific wavelengths included in light collected and condensed by the microlenses to pass therethrough; and
a color filter separating portion arranged between the color filters, wherein
the color filter separating portion is formed by at least one of air, a metal, and a low refractive index material having a refractive index lower than that of a material of the color filters.

9. The photodetection device according to claim 1, wherein each normal pixel has multiple recessed portions in a shape of an inverted pyramid at the light receiving surface of the substrate.

10. The photodetection device according to claim 1, comprising:
a color filter layer arranged between the substrate and the microlens layer, and including multiple color filters that allow light of specific wavelengths included in the light collected and condensed by the microlenses to pass therethrough, wherein
an array pattern of the color filters is a Bayer array modified such that at least one of color filters in the Bayer array is substituted with another color filter to arrange color filters of the same color for the photoelectric conversion parts in the same photoelectric conversion part group, or a modified 2m×2m array in which color filter unit groups are cyclically arranged, each color filter unit group including a 2×2 array of color filter units each including m×m (m is a natural number equal to or greater than 2) color filters of the same color, the 2m×2m array being modified such that at least one of the color filters in the 2m×2m array is substituted with another color filter.

11. The photodetection device according to claim 1, wherein each photoelectric conversion part group includes 2×1, i.e., two, of the photoelectric conversion parts, or n×n (n is a natural number equal to or greater than 2), i.e., n², of the photoelectric conversion parts.

12. The photodetection device according to claim 1, wherein each first pixel separating portion is formed by two of the pixel separating portions that project into a set of two of the photoelectric conversion parts adjacent to the first pixel separating portion from each of two sides in an outer periphery of the set, the two sides lying opposite to each other in a direction perpendicular to a direction in which the two photoelectric conversion parts are arranged, when viewed from a side on which the microlens layer lies.

13. An electronic device comprising:
a photodetection device including
a substrate,
multiple pixels arranged two-dimensionally in the substrate, and including photoelectric conversion parts,
a microlens layer arranged on a side of the substrate on which a light receiving surface of the substrate lies, and including multiple microlenses for concentrating incident light onto the photoelectric conversion parts, and
pixel separating portions arranged between the photoelectric conversion parts in the substrate, and having trench portions, wherein
the multiple pixels include normal pixels and phase difference pixels,
the multiple microlenses include individual-type microlenses each formed for a separate one of the photoelectric conversion parts included in the normal pixels, and shared-type microlenses each formed for a separate one of photoelectric conversion part groups each including the photoelectric conversion parts included in adjacent ones of the phase difference pixels, and
the pixel separating portions include first pixel separating portions arranged between at least some of the photoelectric conversion parts in each photoelectric conversion part group, and second pixel separating portions arranged between the photoelectric conversion parts where none of the first pixel separating portions is arranged, and an end portion of each first pixel separating portion on a side closer to the light receiving surface is positioned on a side of the light receiving surface of the substrate closer to a surface of the substrate opposite to the light receiving surface, while an end portion of each second pixel separating portion on the side closer to the light receiving surface is positioned closer to the light receiving surface than is the end portion of the first pixel separating portion on the side closer to the light receiving surface.
